(19) United States
(12) Patent Application Publication
(10) Pub. No.: US 2026/0149415 A1
(43) Pub. Date: May 28, 2026

(54) BALUN AND POWER AMPLIFYING CIRCUIT

(71) Applicant: Murata Manufacturing Co., Ltd., Nagaokakyo-shi (JP)

(72) Inventor: Kenji TAHARA, Nagaokakyo-shi (JP)

(21) Appl. No.: 19/387,918

(22) Filed: Nov. 13, 2025

(30) Foreign Application Priority Data
Nov. 26, 2024 (JP) 2024-205601

(51) Int. Cl. H03F 1/26; H03F 1/02; H03F 3/213

(52) U.S. Cl. CPC H03F 1/26; H03F 1/0288; H03F 3/213; H03F 2200/06

(57) ABSTRACT

A balun includes: a first wiring line having one end portion connected to a carrier amplifier and another end portion connected to a first reference potential; a second wiring line having one end portion connected to a peaking amplifier and another end portion connected to the first reference potential; a third wiring line having one end portion and another end portion connected to a terminal, the third wiring line being coupled with the first wiring line; a fourth wiring line having one end portion connected to the one end portion of the third wiring line and another end portion, the fourth wiring line being coupled with the second wiring line; and a fifth wiring line having one end portion connected to the another end portion of the fourth wiring line and another end portion that is left open-circuit, the fifth wiring line being electromagnetically coupled with the fourth wiring line.

### CROSS REFERENCE TO RELATED APPLICATION

This application claims priority from Japanese Patent Application No. 2024-205601, filed on November 26, 2024. The content of this application is incorporated herein by reference in its entirety.

### BACKGROUND OF THE DISCLOSURE

### Field of the Disclosure

The present disclosure relates to baluns and power amplifying circuits.

### Description of the Related Art

Doherty amplifying devices for use in power amplifying devices for wireless communication and the like are known in the art (for example, see International Publication No. 2023/074253).

### BRIEF SUMMARY OF THE DISCLOSURE

A transformer described in International Publication No. 2023/074253 includes an input side coil and an output side coil. One end portion of the input side coil is connected to an output terminal of a carrier amplifier via a capacitor. The other end portion of the input side coil is connected to an output terminal of a peaking amplifier via a capacitor and a phase line. One end portion of the output side coil is connected to a signal output terminal. The other end portion of the output side coil is connected to ground.

The transformer of International Publication No. 2023/074253 is configured in such a way that the input side coil and the output side coil are electromagnetically coupled with each other. However, in a high frequency band such as, for example, the sub-terahertz band and the like, effects of parasitic capacitance between lines become greater. Because of this, the transformer's original performance cannot be achieved in some cases. This issue can be dealt with when a Marchand balun is used instead of the transformer. However, when the peaking amplifier is turned off, the frequency variation of the impedance looking from the carrier amplifier toward the following stage thereof increases, and this poses a new issue.

The present disclosure is made in view of such circumstances, and a possible benefit thereof is to provide a balun and a power amplifying circuit that enable the suppression of the frequency variation of the impedance looking from the carrier amplifier toward a following stage thereof when the peaking amplifier is turned off.

A balun according to one aspect of the present disclosure includes: a first wiring line that has one end portion connected to a carrier amplifier and another end portion connected to a first reference potential; a second wiring line that has one end portion connected to a peaking amplifier and another end portion connected to the first reference potential; a third wiring line that has one end portion and another end portion connected to a terminal, the third wiring line being coupled with the first wiring line; a fourth wiring line that has one end portion connected to the one end portion of the third wiring line and another end portion, the fourth wiring line being coupled with the second wiring line; and a fifth wiring line that has one end portion connected to the another end portion of the fourth wiring line and another end portion that is left open-circuit, the fifth wiring line being electromagnetically coupled with the fourth wiring line.

A power amplifying circuit according to another aspect of the present disclosure includes: a carrier amplifier that amplifies a first signal and outputs a first amplified signal from a first output terminal; a peaking amplifier that amplifies a second signal whose phase is different from a phase of the first signal and outputs a second amplified signal from a second output terminal; a first wiring line that has one end portion connected to the first output terminal and another end portion connected to a first reference potential; a second wiring line that has one end portion connected to the second output terminal and another end portion connected to the first reference potential; a third wiring line that has one end portion and another end portion that supplies an output signal, the third wiring line being coupled with the first wiring line; a fourth wiring line that has one end portion connected to the one end portion of the third wiring line and another end portion, the fourth wiring line being coupled with the second wiring line; and a fifth wiring line that has one end portion connected to the another end portion of the fourth wiring line and another end portion that is left open-circuit, the fifth wiring line being electromagnetically coupled with the fourth wiring line.

According to the present disclosure, it becomes possible to provide a balun and a power amplifying circuit that enable the suppression of the frequency variation of the impedance looking from the carrier amplifier toward a following stage thereof when the peaking amplifier is turned off.

### BRIEF DESCRIPTION OF THE SEVERAL VIEWS OF THE DRAWINGS

FIG. 1 is a circuit diagram of a power amplifying circuit 201;

FIG. 2 is a circuit diagram of a power amplifying circuit 291 that serves as a reference example;

FIG. 3 is a diagram illustrating, on the Smith chart, a simulation result of frequency variation of S11 when both a carrier amplifier 51c and a peaking amplifier 51p are in operation in the power amplifying circuit 291 that serves as the reference example;

FIG. 4 is a diagram illustrating a simulation result of frequency variation of S21 when both the carrier amplifier 51c and the peaking amplifier 51p are in operation in the power amplifying circuit 291 that serves as the reference example;

FIG. 5 is a diagram illustrating, on the Smith chart, a simulation result of the frequency variation of S11 when the peaking amplifier 51p is in an off-state, compared with FIG. 3;

FIG. 6 is a diagram illustrating a simulation result of the frequency variation of S21 when the peaking amplifier 51p is in the off-state, compared with FIG. 4;

FIG. 7 is a schematic circuit diagram for describing a reason why the frequency variation of S11 becomes greater in the power amplifying circuit 291;

FIG. 8 is a diagram for describing the frequency variation of S11 in the power amplifying circuit 201 on the Smith chart;

FIG. 9 is a schematic circuit diagram for describing a reason why the frequency variation of S11 is suppressed in the power amplifying circuit 201;

FIG. 10 is a diagram illustrating a simulation result of the frequency variation of S21 when the peaking amplifier 51p is in the off-state in the power amplifying circuit 201;

FIG. 11 is a diagram illustrating, on the Smith chart, a simulation result of the frequency variation of S11 when the peaking amplifier 51p is in the off-state in the power amplifying circuit 201;

FIG. 12 is a plan view of a balun 101 seeing from the top side;

FIG. 13 is a circuit diagram of a power amplifying circuit 202;

FIG. 14 is a diagram illustrating, on the Smith chart, a simulation result of the frequency variation of S11 when both the carrier amplifier 51c and the peaking amplifier 51p are in operation in the power amplifying circuit 202;

FIG. 15 is a plan view of a balun 102 seeing from the top side;

FIG. 16 is a circuit diagram of a power amplifying circuit 203;

FIG. 17 is a diagram illustrating, on the Smith chart, a simulation result of the frequency variation of S11 when both the carrier amplifier 51c and the peaking amplifier 51p are in operation in the power amplifying circuit 203;

FIG. 18 is a plan view of a balun 103 seeing from the top side;

FIG. 19 is a circuit diagram of a power amplifying circuit 204; and

FIG. 20 is a circuit diagram of a power amplifying circuit 205.

### DETAILED DESCRIPTION OF THE DISCLOSURE

Hereinafter, embodiments of the present disclosure will be described in detail while referring to the drawings. Note that the same reference characters are assigned to the same constituent elements, and overlapping descriptions are omitted as much as possible.

### First Embodiment

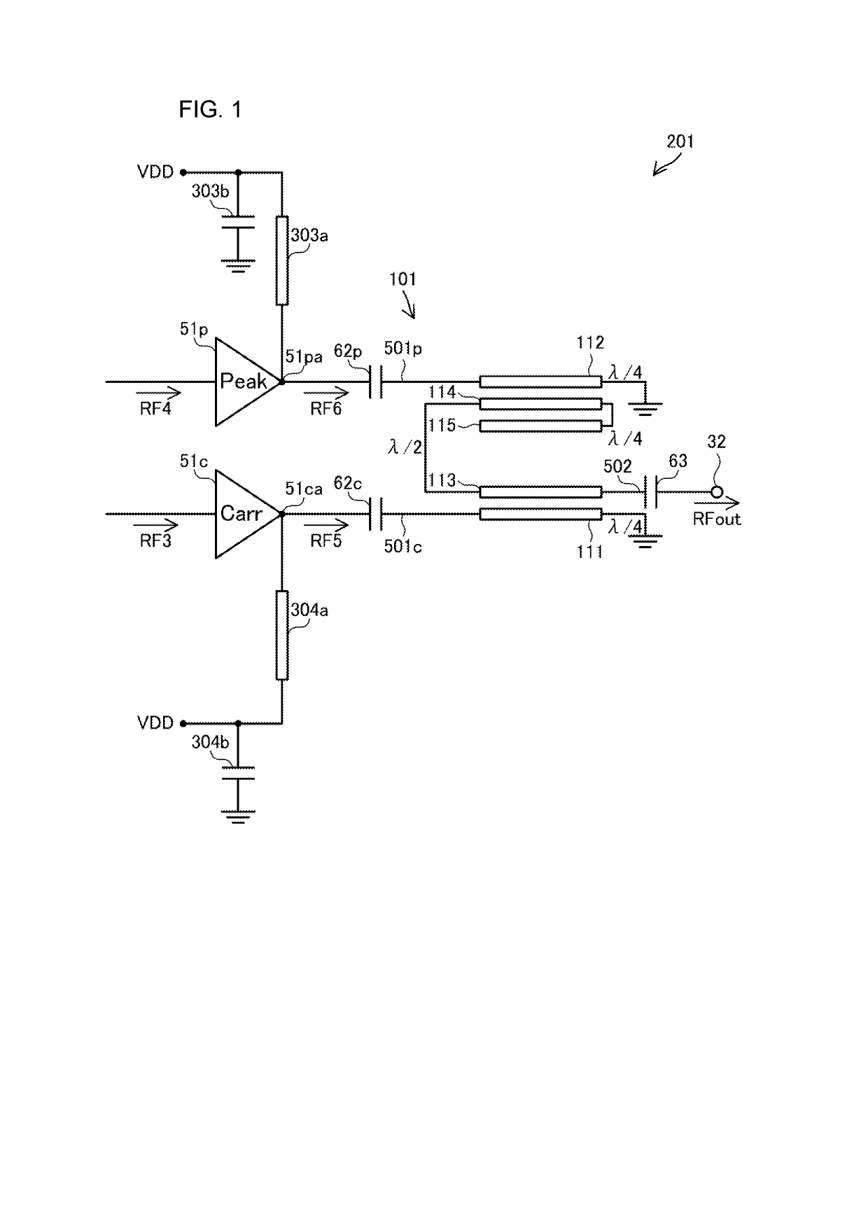

A power amplifying circuit 201 according to the first embodiment is now described. FIG. 1 is a circuit diagram of the power amplifying circuit 201. As illustrated in FIG. 1, the power amplifying circuit 201 includes a carrier amplifier 51c, a peaking amplifier 51p, capacitors 62p, 62c, and 63, a balun 101, wiring lines 303a and 304a, and capacitors 303b and 304b.

The carrier amplifier 51c and the peaking amplifier 51p include amplifying transistors (not illustrated). The balun 101 includes a wiring line 111 (first wiring line), a wiring line 112 (second wiring line), a wiring line 113 (third wiring line), a wiring line 114 (fourth wiring line), and a wiring line 115 (fifth wiring line). The balun 101 is, for example, a Marchand balun.

In the present embodiment, the transistors are each formed of, for example, a bipolar transistor such as a heterojunction bipolar transistor (HBT) or the like. Note that the transistors may alternatively be each formed of another transistor such as a field effect transistor (MOSFET: Metal-oxide-semiconductor Field-Effect transistor) or the like. In that case, the base, the collector, and the emitter may be replaced with the gate, the drain, and the source, respectively.

The carrier amplifier 51c and the peaking amplifier 51p of the power amplifying circuit 201 operate as a Doherty amplifier.

The carrier amplifier 51c amplifies a signal RF3 (first signal) supplied from a circuit in the preceding stage and outputs an amplified signal RF5 (first amplified signal) from an output terminal 51ca (first output terminal).

The peaking amplifier 51p amplifies a signal RF4 (second signal) supplied from a circuit in the preceding stage and outputs an amplified signal RF6 (second amplified signal) from an output terminal 51pa (second output terminal).

The signal RF4 and the signal RF3 are different in phase. In the present embodiment, for example, the signal RF3 and the signal RF4 are different in phase by approximately 180 degrees. The frequency of the signals RF3 and RF4 is, for example, in a sub-terahertz band. Specifically, the frequencies of the signals RF3 and RF4 are, for example, in the range between 90 GHz and 300 GHz.

Particularly, the amplifying transistor included in the carrier amplifier 51c operates by a power supply voltage VDD supplied via the wiring line 304a, which functions as an inductor, and the output terminal 51ca. The capacitor 304b is a bypass capacitor, and has one end portion to which the power supply voltage VDD is supplied and the other end portion connected to ground. Here, the potential of the ground is one example of a first reference potential.

The amplifying transistor included in the carrier amplifier 51c operates, for example, in class A or class AB by a bias supplied from a bias circuit (not illustrated).

The amplifying transistor included in the peaking amplifier 51p operates by a power supply voltage VDD supplied via the wiring line 303a, which functions as an inductor, and the output terminal 51pa. The capacitor 303b is a bypass capacitor, and has one end portion to which the power supply voltage VDD is supplied and the other end portion connected to the ground.

The amplifying transistor included in the peaking amplifier 51p operates, for example, in class C by a bias supplied from a bias circuit (not illustrated).

A line 501c has one end portion connected to the output terminal 51ca of the carrier amplifier 51c and the other end portion, and the amplified signal RF5 is transmitted through the line 501c.

A line 501p has one end portion connected to the output terminal 51pa of the peaking amplifier 51p and the other end portion, and the amplified signal RF6 is transmitted through the line 501p.

The capacitors 62c and 62p each have, for example, DC-cut capability and are provided in the lines 501c and 501p, respectively. Note that the capacitors 62c and 62p may also have capability of providing impedance matching between the carrier amplifier 51c and the balun 101 and the peaking amplifier 51p and the balun 101, respectively.

Particularly, the capacitor 62c has one end portion connected to the output terminal 51ca of the carrier amplifier 51c via part of the line 501c and the other end portion connected to the wiring line 111 via the other part of the line 501c.

The capacitor 62p has one end portion connected to the output terminal 51pa of the peaking amplifier 51p via part of the line 501p and the other end portion connected to the wiring line 112 via the other part of the line 501p.

The balun 101 combines the amplified signals RF5 and RF6, which are respectively supplied from the carrier amplifier 51c and the peaking amplifier 51p, to convert these signals into an output signal RFout that is a single-ended signal. Furthermore, the balun 101 provides impedance matching between the amplifiers, namely the carrier amplifier 51c and the peaking amplifier 51p, and a circuit in the following stage that follows an output terminal 32, which is, for example, an antenna.

Particularly, the wiring line 111 of the balun 101 has one end portion connected to the carrier amplifier 51c and the other end portion connected to the first reference potential. Particularly, the wiring line 111 has the one end portion connected to the output terminal 51ca of the carrier amplifier 51c and the other end portion connected to the ground. More particularly, the one end portion of the wiring line 111 is connected to the other end portion of the line 501c. The amplified signal RF5 outputted from the carrier amplifier 51c is supplied to the one end portion of the wiring line 111.

The wiring line 112 has one end portion connected to the peaking amplifier 51p and the other end portion connected to the first reference potential. Particularly, the wiring line 112 has the one end portion connected to the output terminal 51pa of the peaking amplifier 51p and the other end portion connected to the ground. More particularly, the one end portion of the wiring line 112 is connected to the other end portion of the line 501p. The amplified signal RF6 outputted from the peaking amplifier 51p is supplied to the one end portion of the wiring line 112.

The wiring line 113 has one end portion and the other end portion connected to the output terminal 32. The wiring line 113 is coupled with the wiring line 111. This coupling is, for example, coupling between the lines. Particularly, the other end portion of the wiring line 113 is connected to a line 502 through which the output signal RFout is transmitted. The other end portion of the wiring line 113 supplies the output signal RFout to the output terminal 32 via the line 502.

The wiring line 114 has one end portion connected to the one end portion of the wiring line 113 and the other end portion, and is coupled with the wiring line 112. This coupling is, for example, coupling between the lines.

The wiring line 115 has one end portion connected to the other end portion of the wiring line 114 and the other end portion that is left open-circuit, and is coupled with the wiring line 114 electromagnetically. This coupling is, for example, coupling between the lines.

Each of the wiring lines 111, 112, and 115 is a quarter-wavelength line. Particularly, the time it takes the amplified signal RF5 or RF6 to propagate from the one end portion to the other end portion of the wiring line 111, 112, or 115 is approximately one-quarter the cycle of the amplified signal RF5 or RF6. In other words, each of the electrical lengths of the wiring lines 111, 112, and 115 is approximately one-quarter the wavelength of the amplified signal RF5 or RF6.

The line 502 has one end portion connected to the other end portion of the wiring line 113 and the other end portion connected to the output terminal 32.

The capacitor 63 is provided in the line 502. Particularly, the capacitor 63 has one end portion connected to the other end portion of the wiring line 113 via part of the line 502 and the other end portion connected to the output terminal 32 via the other part of the line 502.

The wiring line formed by combining the wiring lines 113 and 114 is a half-wavelength line. Particularly, the time it takes the output signal RFout to propagate from the other end portion of the wiring line 113 to the other end portion of the wiring line 114 is approximately one-half the cycle of the output signal RFout. In other words, the electrical length from the other end portion of the wiring line 113 to the other end portion of the wiring line 114 is approximately one-half the wavelength of the output signal RFout. Note that each of the wiring lines 113 and 114 is, for example, a quarter-wavelength line.

Note that in the present embodiment, the configuration is described in which the balun 101 is connected to the output sides of the carrier amplifier 51c and the peaking amplifier 51p. However, the configuration is not limited thereto. A configuration in which the balun 101 is connected to the input sides of the carrier amplifier 51c and the peaking amplifier 51p may alternatively be used.

### Reference Example

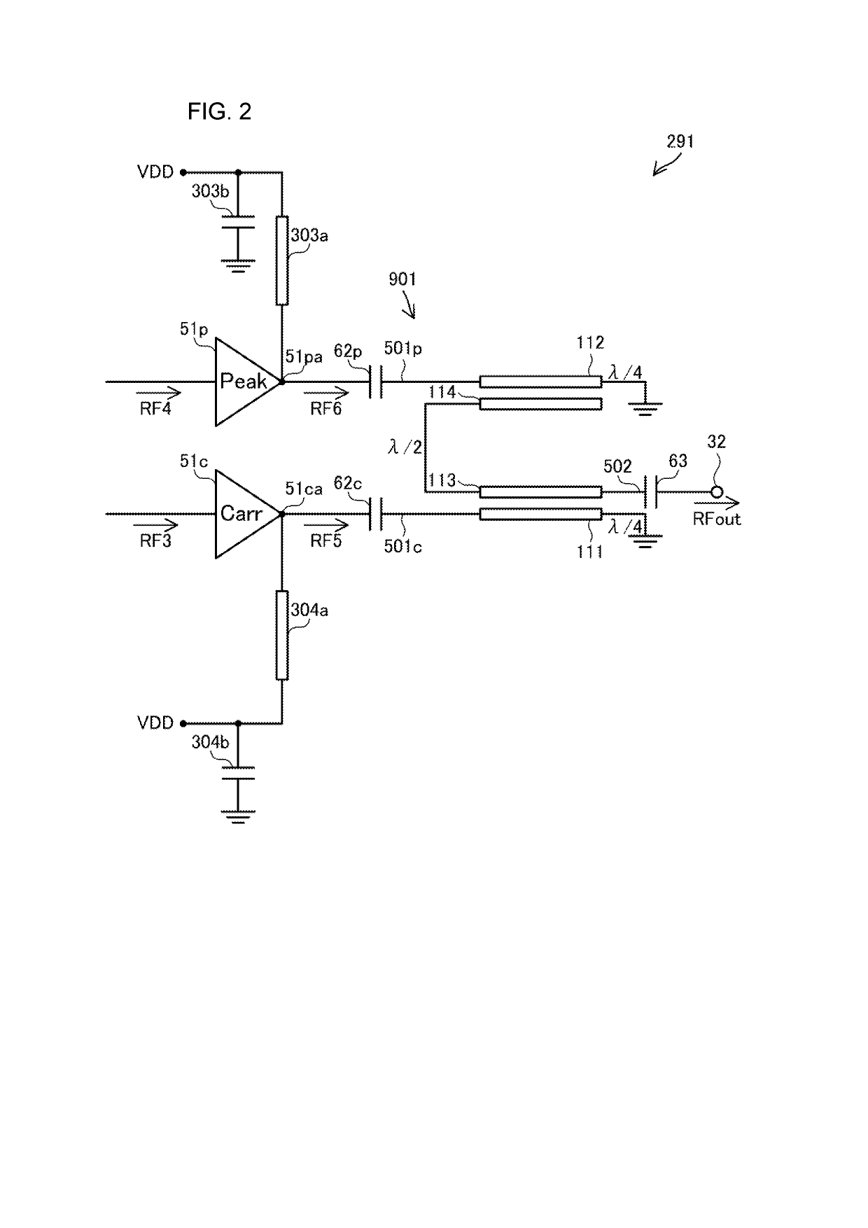

A power amplifying circuit 291 that serves as a reference example is now described. FIG. 2 is a circuit diagram of the power amplifying circuit 291 that serves as a reference example.

Compared with the power amplifying circuit 201 (see FIG. 1), the power amplifying circuit 291 includes a balun 901 in place of the balun 101. Compared with the balun 101 (see FIG. 1), the wiring line 115 is not provided in the balun 901. That is to say, the wiring line 114 has one end portion connected to the one end portion of the wiring line 113 and the other end portion that is left open-circuit, and is coupled with the wiring line 112.

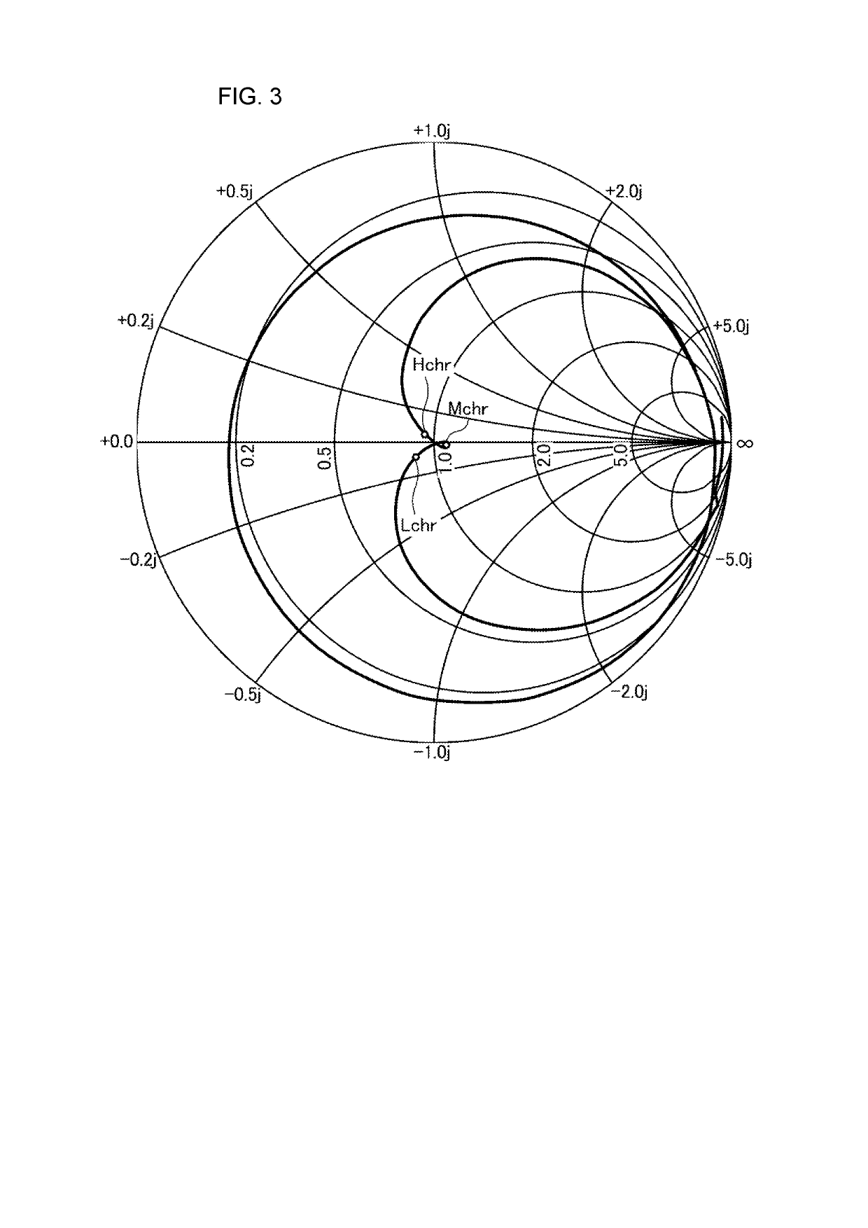

FIG. 3 is a diagram illustrating, on the Smith chart, a simulation result of frequency variation of S11 when both the carrier amplifier 51c and the peaking amplifier 51p are in operation in the power amplifying circuit 291 that serves as the reference example. Here, S11 is the S (scattering) parameter of a signal that is incident on the capacitor 62c from the carrier amplifier 51c.

As illustrated in FIG. 3, S11 at the frequencies of 120 GHz, 130 GHz, and 140 GHz, which are included in the fundamental wave band of the amplified signal RF5, are denoted by Lchr, Mchr, and Hchr, respectively.

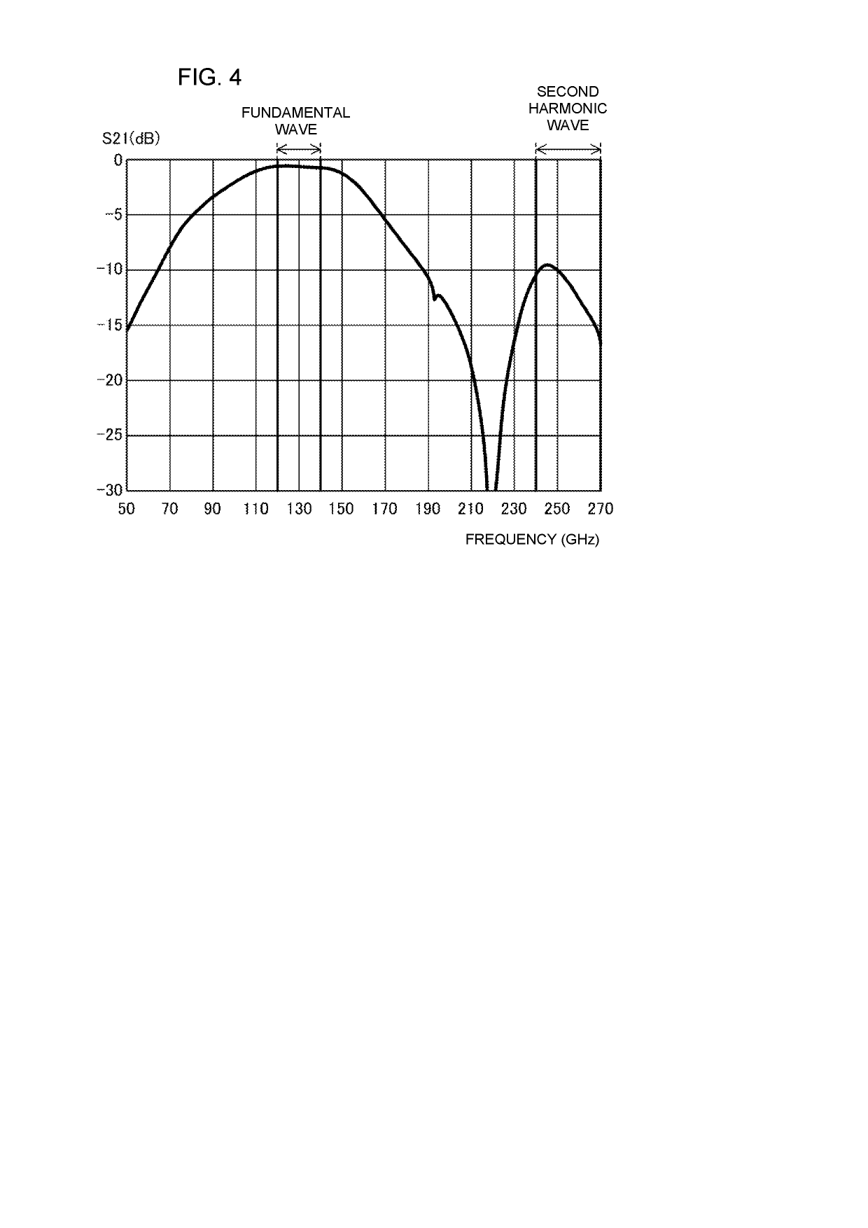

FIG. 4 is a diagram illustrating a simulation result of frequency variation of S21 when both the carrier amplifier 51c and the peaking amplifier 51p are in operation in the power amplifying circuit 291 that serves as the reference example. Here, S21 is the S parameter of a signal that passes through the balun 901 from the carrier amplifier 51c. Note that the vertical axis represents S21 in a unit of "dB". The horizontal axis represents the frequency in a unit of "GHz".

As illustrated in FIG. 3 and FIG. 4, the impedance matching is provided between the amplifiers, namely the carrier amplifier 51c and the peaking amplifier 51p, and a circuit in the following stage of the output terminal 32, and the reflection of the fundamental wave of the amplified signal RF5 is suppressed.

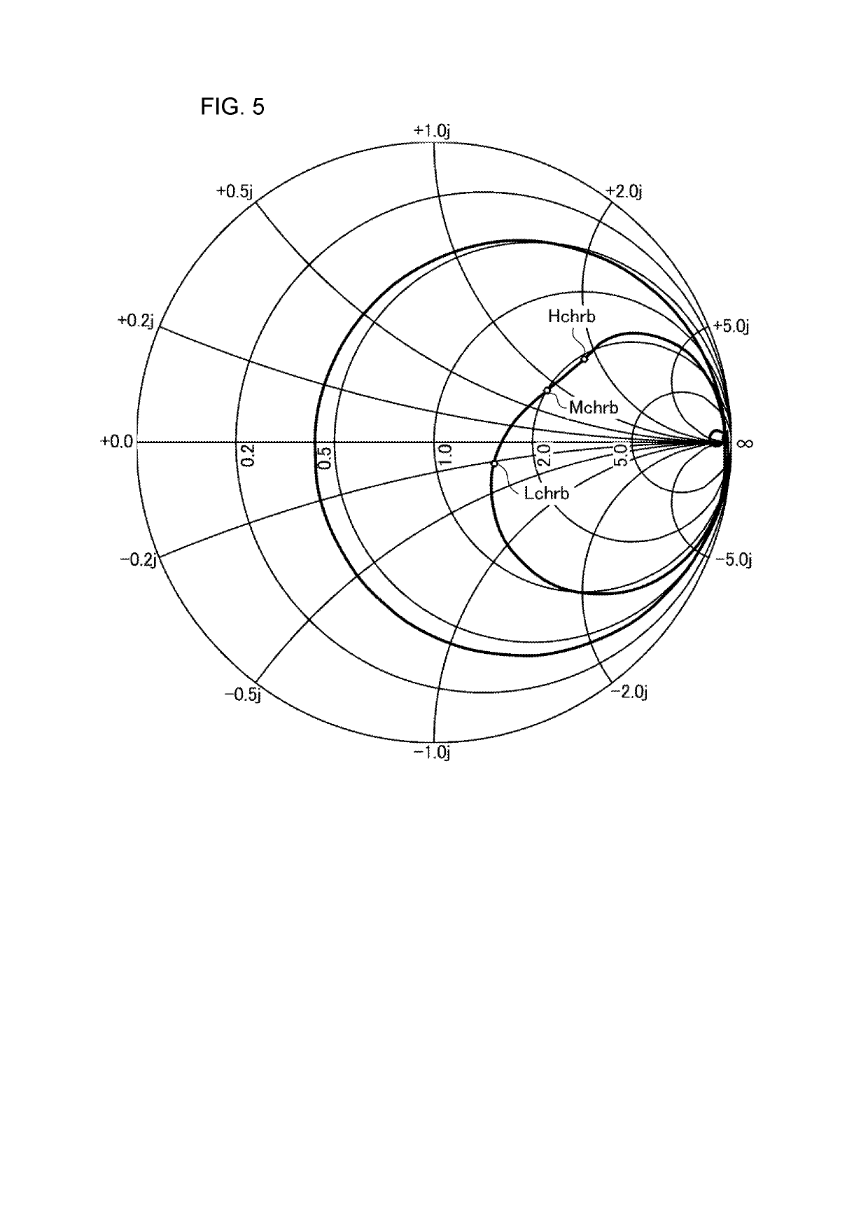

Compared with FIG. 3, FIG. 5 is a diagram illustrating, on the Smith chart, a simulation result of the frequency variation of S11 when the peaking amplifier 51p is in the off-state. In the case where the peaking amplifier 51p of the power amplifying circuit 291 is in the off-state, S11 at the frequencies of 120 GHz, 130 GHz, and 140 GHz are denoted by Lchrb, Mchrb, and Hchrb, respectively.

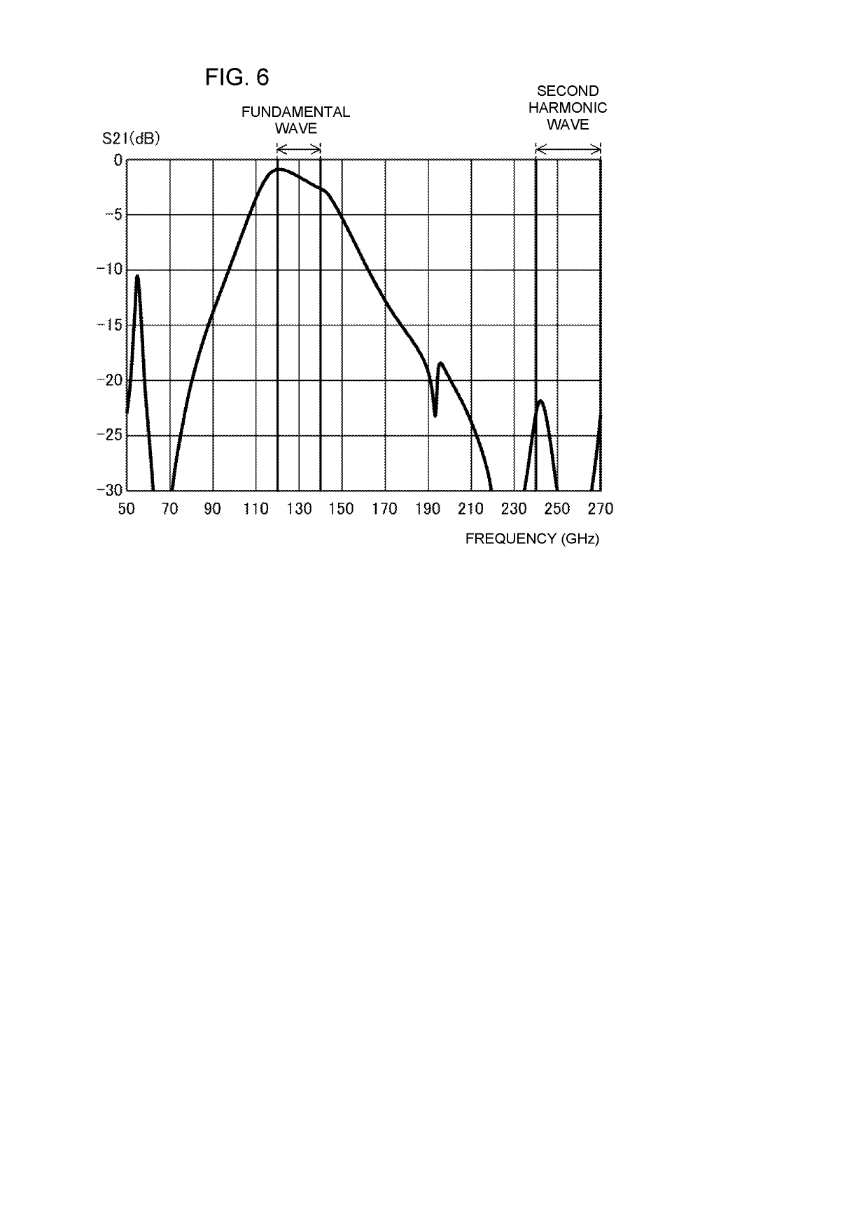

Compared with FIG. 4, FIG. 6 is a diagram illustrating a simulation result of the frequency variation of S21 when the peaking amplifier 51p is in the off-state. Note that the description of FIG. 4 applies correspondingly to FIG. 6.

As illustrated in FIG. 5 and FIG. 6, in the range between 120 GHz and 140 GHz, the frequency variation of S11 becomes greater (see FIG. 5) compared with the frequency variation of S11 when both the carrier amplifier 51c and the peaking amplifier 51p are in operation (see FIG. 3).

With regard to S21, in the range between 120 GHz and 140 GHz, when both the carrier amplifier 51c and the peaking amplifier 51p are in operation, the frequency variation is nearly flat (see FIG. 4). However, when the peaking amplifier 51p is in the off-state, S21 decreases on the high frequency side (see FIG. 6).

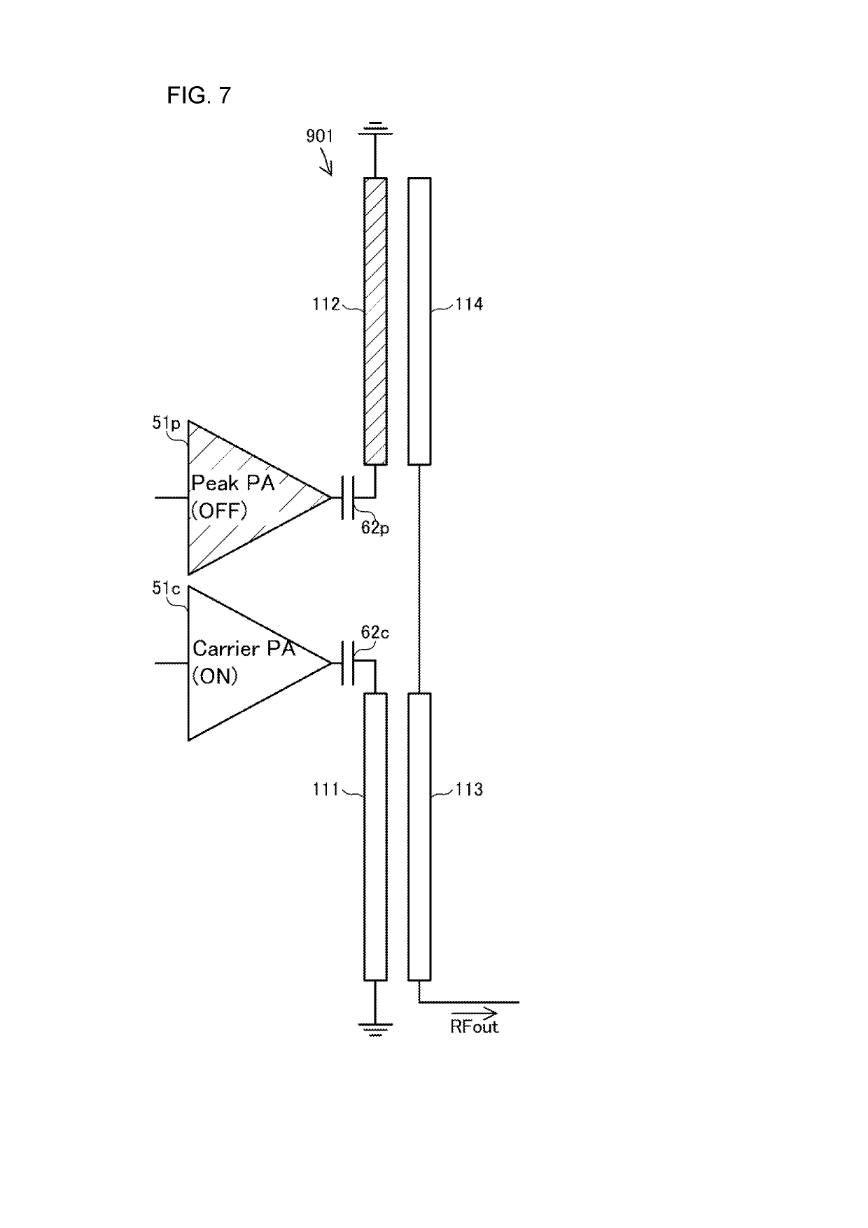

FIG. 7 is a schematic circuit diagram for describing a reason why the frequency variation of S11 becomes greater in the power amplifying circuit 291. As illustrated in FIG. 7, when the peaking amplifier 51p is in the off-state, the wiring line 112 does not function. Thus, the wiring line 114 is simply connected to the other end portion of the wiring line 113.

The wiring line 114 functions as an open stub having inductive properties, and the input impedance to the wiring line 114 demonstrates significant frequency dependence. Because of this, in the range between 120 GHz and 140 GHz, the frequency variation of S11 becomes greater (see FIG. 5).

Furthermore, of the signals generated by the coupling of the wiring lines 111 and 113, reflected waves reflected at the wiring line 114 demonstrate significant frequency dependence. Thus, in the range between 120 GHz and 140 GHz, the frequency variation of S21 does not become nearly flat, and S21 decreases on the high frequency side (see FIG. 6).

### Effects

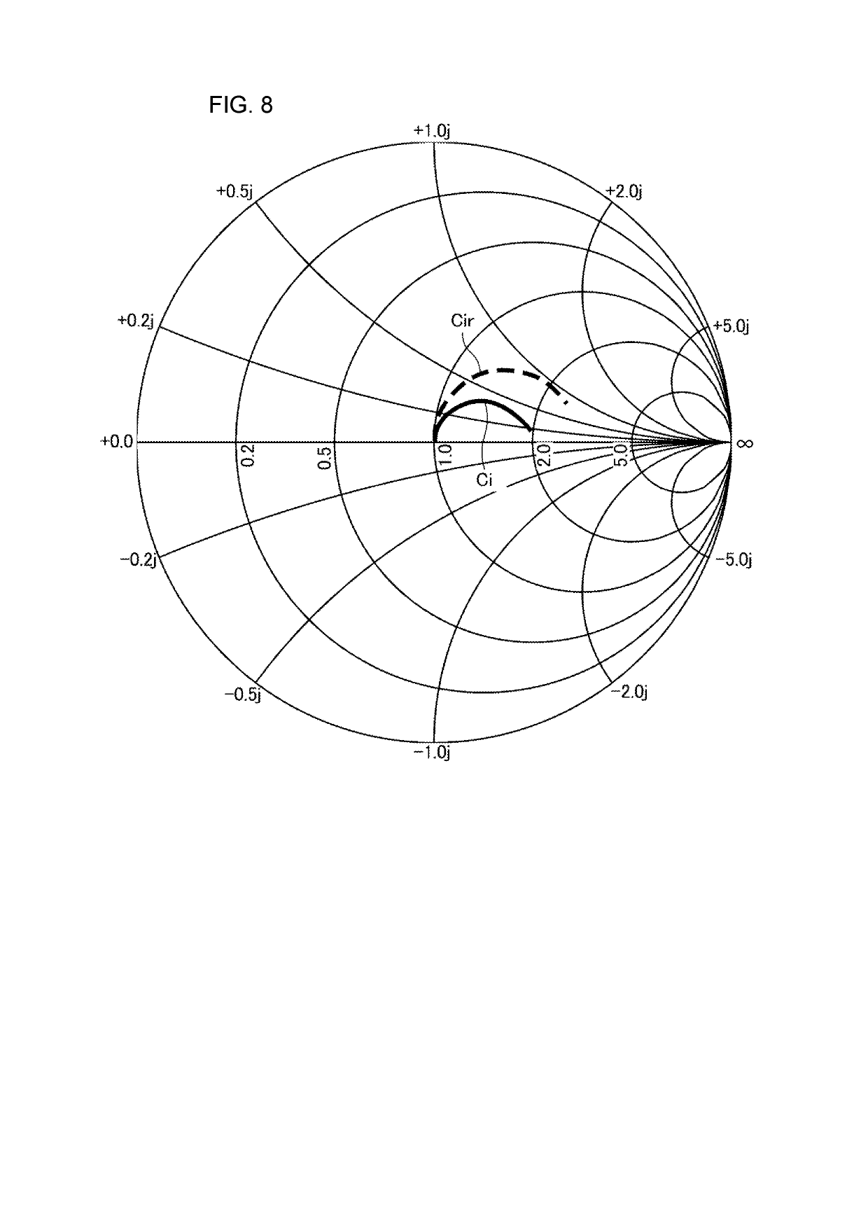

FIG. 8 is a diagram for describing the frequency variation of S11 in the power amplifying circuit 201 on the Smith chart. In FIG. 8, a curve Ci represents the change of S11 when the peaking amplifier 51p is turned from the on-state to the off-state in the case where the wiring line 114 and the wiring line 115 are arranged in such a manner as to be coupled with each other electromagnetically.

A curve Cir represents the change of S11 when the peaking amplifier 51p is turned from the on-state to the off-state in the case where the wiring line 114 and the wiring line 115 are arranged in such a manner as not to be coupled with each other electromagnetically.

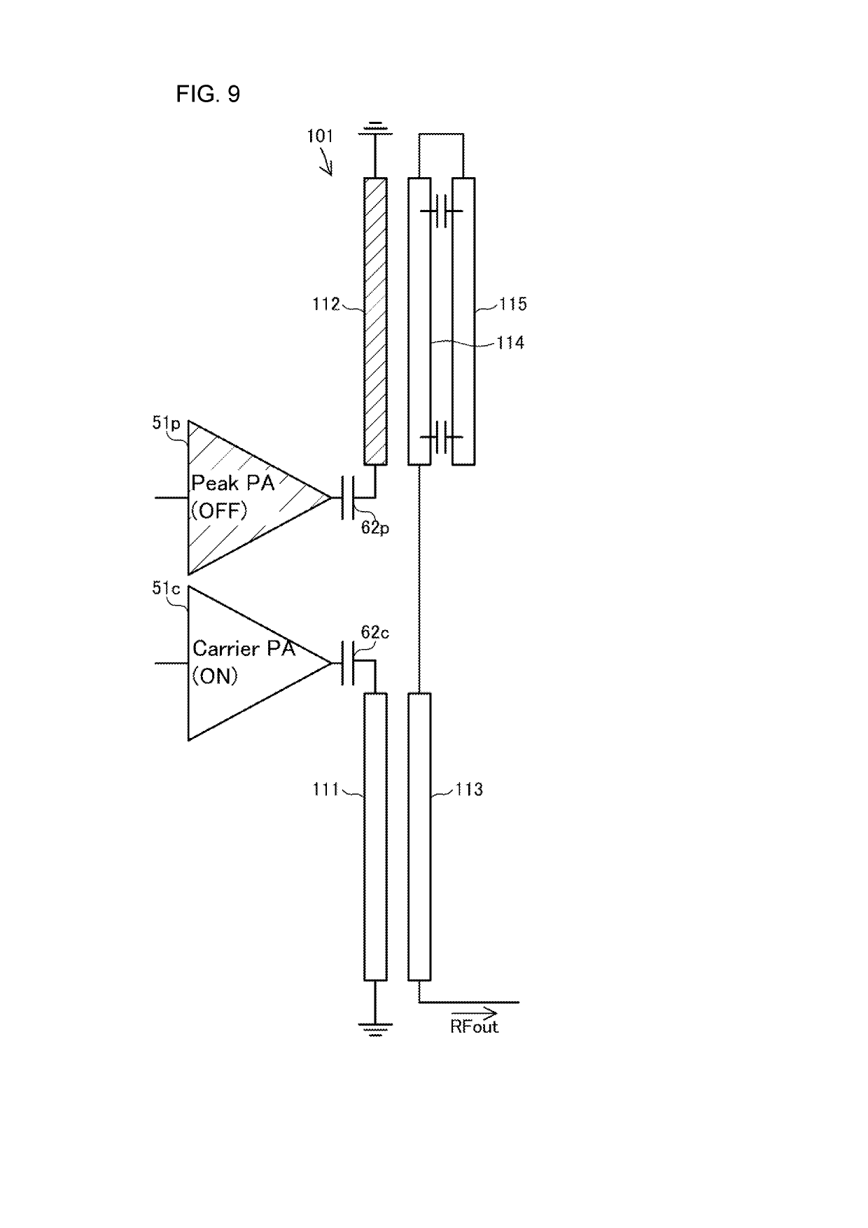

FIG. 9 is a schematic circuit diagram for describing a reason why the frequency variation of S11 is suppressed in the power amplifying circuit 201.

As illustrated in FIG. 8 and FIG. 9, in the power amplifying circuit 201, the other end portion of the wiring line 114 is connected to the wiring line 115.

If the wiring line 114 and the wiring line 115 were not coupled with each other electromagnetically, the wiring lines 114 and 115 would function as an open stub having inductive properties. Thus, as represented by the curve Cir, S11 changes away from the real axis toward the inductive side. In such a case, the frequency variation of S11 becomes greater.

In contrast, in the power amplifying circuit 201, the wiring line 114 is electromagnetically coupled with the wiring line 115. This enables capacitive coupling between the wiring lines 114 and 115, and thus, it becomes possible to suppress the inductive properties of the wiring lines 114 and 115 of the power amplifying circuit 201.

Specifically, as represented by the curve Ci, S11 can be changed closer to the capacitive side, which is the real axis side, than the curve Cir. Thus, it becomes possible to suppress the frequency variation of S11. The frequency dependence of the input impedance to the wiring line 114 can be reduced. As a result, it becomes possible to reduce the frequency dependence of the reflected waves reflected at the wiring line 114, which constitute part of the signals generated by the coupling of the wiring lines 111 and 113.

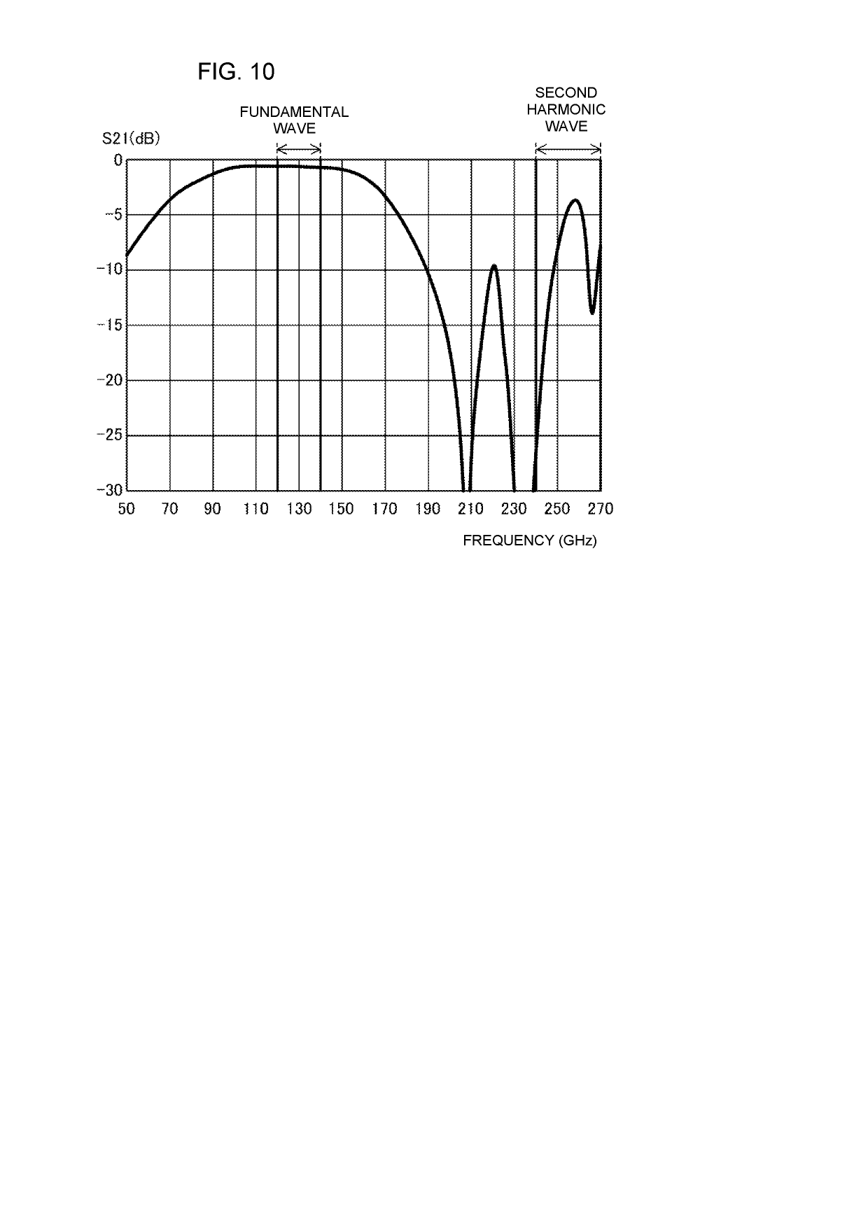

FIG. 10 is a diagram illustrating a simulation result of the frequency variation of S21 when the peaking amplifier 51p is in the off-state in the power amplifying circuit 201. As illustrated in FIG. 10, in the power amplifying circuit 201, it becomes possible to make the frequency variation of S21 nearly flat in the range between 120 GHz and 140 GHz.

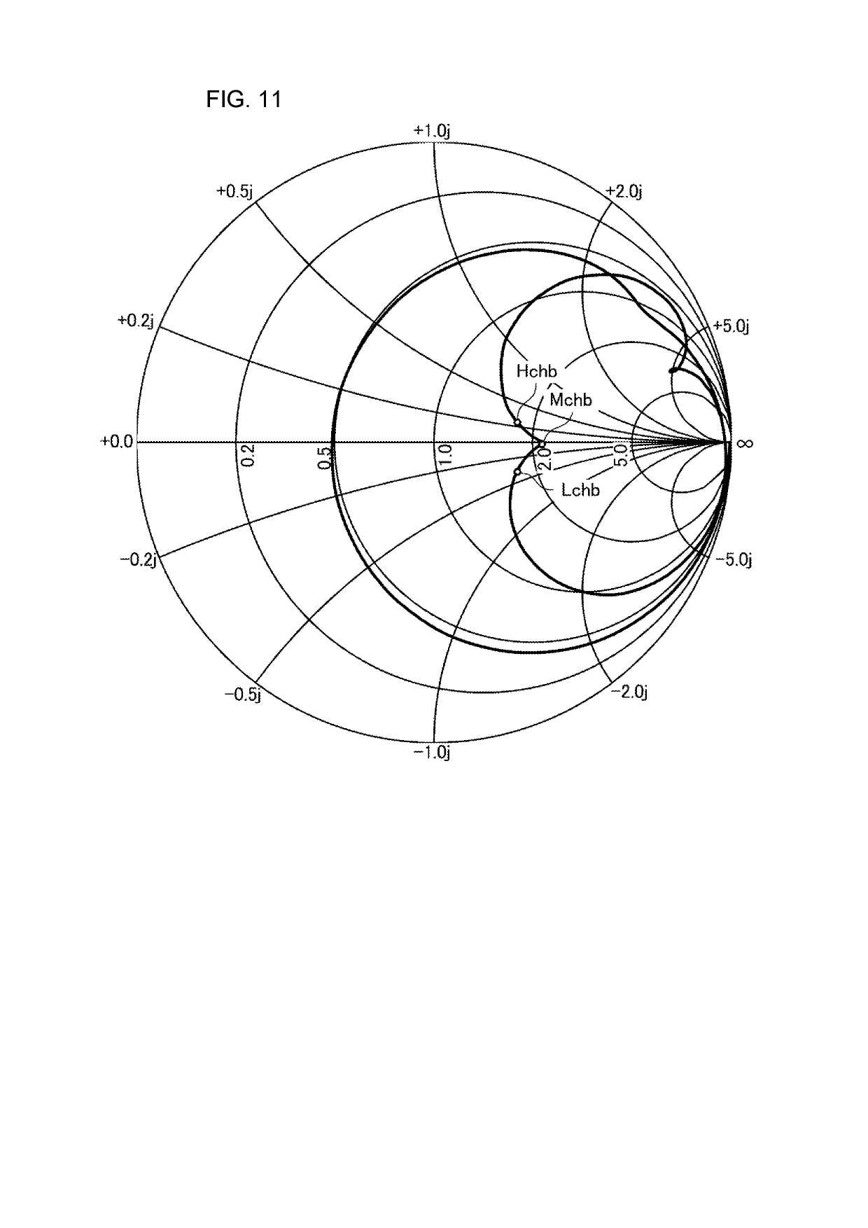

FIG. 11 is a diagram illustrating, on the Smith chart, a simulation result of the frequency variation of S11 when the peaking amplifier 51p is in the off-state in the power amplifying circuit 201. In the case where the peaking amplifier 51p of the power amplifying circuit 201 is in the off-state, S11 at the frequencies of 120 GHz, 130 GHz, and 140 GHz are denoted by Lchb, Mchb, and Hchb, respectively.

As illustrated in FIG. 11, in the power amplifying circuit 201, it becomes possible to suppress the frequency variation of S11 in the range between 120 GHz and 140 GHz.

### Layout of Balun 101

The layout of the balun 101 is now described. In each drawing, the x-axis, the y-axis, and the z-axis may be illustrated. The x-axis, the y-axis, and the z-axis form three-dimensional Cartesian coordinates of right-handed system. In the following sections, the direction of arrow of the x-axis may be referred to as x-axis plus-side, and the direction opposite to the arrow may be referred to as x-axis minus-side. The same applies to the other axes. Note that the z-axis plus-side and the z-axis minus-side may also be referred to as "top side" and "bottom side", respectively. Furthermore, planes orthogonal to the x-axis, the y-axis, and the z-axis may be referred to as yz-plane, zx-plane, and xy-plane, respectively. Here, the direction that rotates in a clockwise manner when viewed from the top side to the bottom side is defined as clockwise direction cw. Furthermore, the direction that rotates in a counterclockwise manner when viewed from the top side to the bottom side is defined as counterclockwise direction ccw.

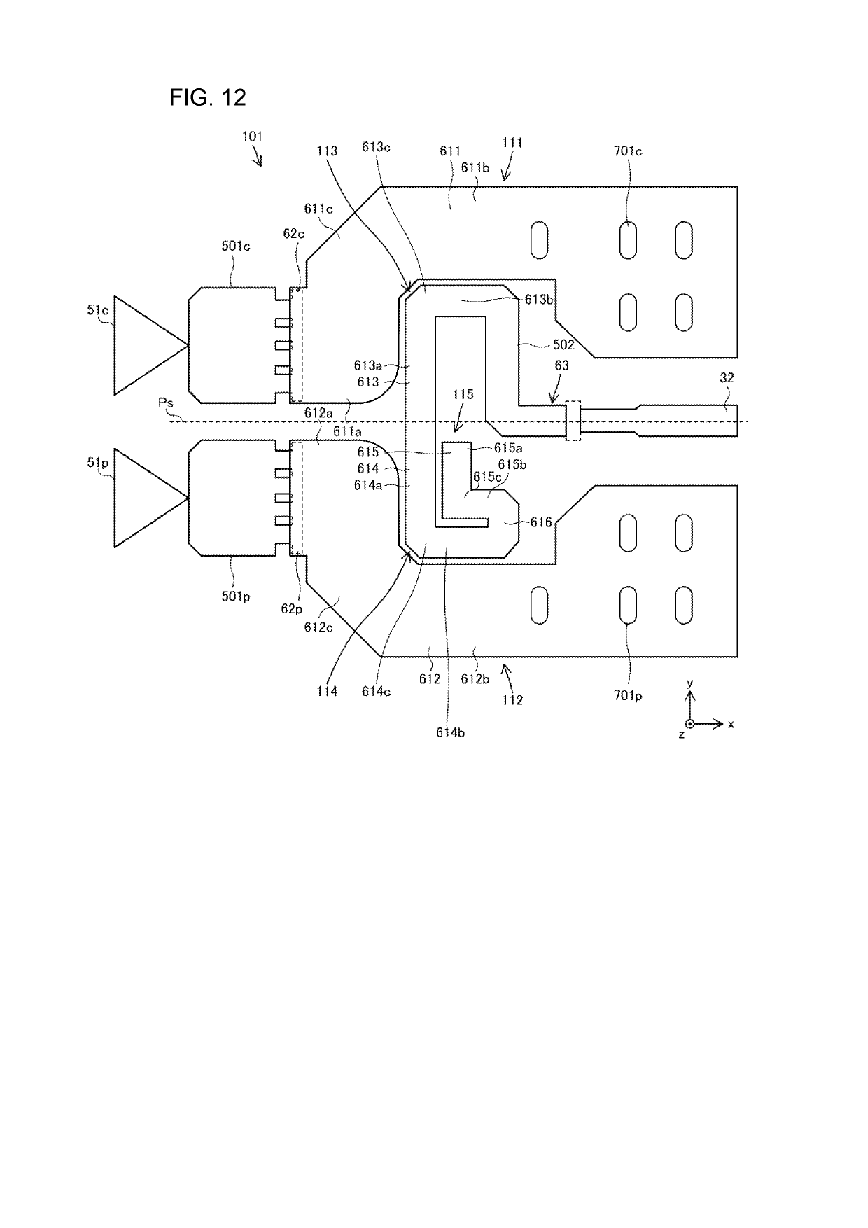

FIG. 12 is a plan view of the balun 101 seeing from the top side. As illustrated in FIG. 12, the wiring lines 111, 112, 113, 114, and 115 are formed of metal electrodes 611, 612 (third conductive member), 613, 614 (first conductive member), and 615 (second conductive member), respectively.

Particularly, the wiring line 111 is formed of the metal electrode 611 that extends from one end portion of the wiring line 111 to the other end portion of the wiring line 111. The wiring line 112 is formed of the metal electrode 612 that extends from one end portion of the wiring line 112 to the other end portion of the wiring line 112. The wiring line 113 is formed of the metal electrode 613 that extends from one end portion of the wiring line 113 to the other end portion of the wiring line 113. The wiring line 114 is formed of the metal electrode 614 that extends from one end portion of the wiring line 114 to the other end portion of the wiring line 114. The wiring line 115 is formed of the metal electrode 615 that extends from one end portion of the wiring line 115 to the other end portion of the wiring line 115.

The metal electrodes 611, 612, 613, 614, and 615 are provided along a first plane. In the present embodiment, the first plane is approximately parallel to the xy-plane. The first plane is, for example, a surface of a semiconductor chip. Note that the first plane may alternatively be a surface of an insulation layer provided in the inside of the semiconductor chip.

The metal electrodes 611 and 612 have symmetric shapes with respect to the plane parallel to the zx-plane (hereinbelow, may also be referred to as symmetry plane Ps). The capacitors 62c and 62p have symmetric shapes with respect to the symmetry plane Ps. The lines 501c and 501p have symmetric shapes with respect to the symmetry plane Ps.

The metal electrode 611 has extending portions 611a and 611b and a corner portion 611c. In the corner portion 611c, the extending direction changes. In the present embodiment, the extending direction of the metal electrode 611 that extends from one end portion of the wiring line 111 to the other end portion of the wiring line 111 changes from the y-axis plus-direction to the x-axis plus-direction in the corner portion 611c.

The metal electrode 612 has extending portions 612a and 612b and a corner portion 612c (third corner portion). In the corner portion 612c, the extending direction changes. In the present embodiment, the extending direction of the metal electrode 612 that extends from one end portion of the wiring line 112 to the other end portion of the wiring line 112 changes from the y-axis minus-direction to the x-axis plus-direction in the corner portion 612c.

The extending portion 611a and the extending portion 612a extend from the corner portion 611c and the corner portion 612c, respectively, in such a way that the extending portion 611a and the extending portion 612a approach each other.

Specifically, the extending portion 611a extends from the corner portion 611c toward the y-axis minus-direction. The line 501c is connected to the x-axis minus-side of the extending portion 611a. The capacitor 62c is provided in the line 501c. The line 501c electrically connects the extending portion 611a to the carrier amplifier 51c.

The extending portion 612a extends from the corner portion 612c toward the y-axis plus-direction. The line 501p is connected to the x-axis minus-side of the extending portion 612a. The capacitor 62p is provided in the line 501p. The line 501p electrically connects the extending portion 612a to the peaking amplifier 51p.

The extending portion 611b and the extending portion 612b extend from the corner portion 611c and the corner portion 612c, respectively, in the same direction.

Specifically, the extending portion 611b extends from the corner portion 611c toward the x-axis plus-direction. Part of the extending portion 611b on the x-axis plus-side is electrically connected to an electrode that has the potential of the ground via an interlayer via 701c.

The extending portion 612b extends from the corner portion 612c toward the x-axis plus-direction. Part of the extending portion 612b on the x-axis plus-side is electrically connected to an electrode that has the potential of the ground via an interlayer via 701p.

The metal electrode 613 has extending portions 613a and 613b and a corner portion 613c. The corner portion 613c is positioned farther inward with respect to the corner portion 611c and extends alongside the corner portion 611c.

In the present embodiment, the extending direction of the metal electrode 613 that extends from one end portion of the wiring line 113 to the other end portion of the wiring line 113 changes from the y-axis plus-direction to the x-axis plus-direction in the corner portion 613c.

The metal electrode 614 has extending portions 614a and 614b (first extending portion) and a corner portion 614c (first corner portion). The corner portion 614c is positioned farther inward with respect to the corner portion 612c and extends alongside the corner portion 612c. In other words, the corner portion 612c is positioned farther outward with respect to the corner portion 614c and extends alongside the corner portion 614c.

In the present embodiment, the extending direction of the metal electrode 614 that extends from one end portion of the wiring line 114 to the other end portion of the wiring line 114 changes from the y-axis minus-direction to the x-axis plus-direction in the corner portion 614c.

The extending portion 613a and the extending portion 614a extend from the corner portion 613c and the corner portion 614c, respectively, in such a way that the extending portion 613a and the extending portion 614a approach each other. Specifically, the extending portion 613a is positioned on the x-axis plus-side of the extending portion 611a and extends alongside the extending portion 611a from the corner portion 613c toward the y-axis minus-direction. The extending portion 614a is positioned on the x-axis plus-side of the extending portion 612a, extends alongside the extending portion 612a from the corner portion 614c toward the y-axis plus-direction, and is connected to the extending portion 613a.

The extending portions 613b and 614b extend along the x-axis direction (first direction). Specifically, the extending portions 613b and 614b extend from the corner portion 613c and the corner portion 614c, respectively, in the same direction. More specifically, the extending portion 613b is positioned on the y-axis minus-side of the extending portion 611b and extends alongside the extending portion 611b from the corner portion 613c toward the x-axis plus-direction. The extending portion 614b is positioned on the y-axis plus-side of the extending portion 612b and extends alongside the extending portion 612b from the corner portion 614c toward the x-axis plus-direction.

The metal electrode 615 is positioned farther inward with respect to the corner portion 614c. Particularly, the metal electrode 615 has extending portions 615a and 615b (second extending portion) and a corner portion 615c.

The corner portion 615c (second corner portion) is positioned farther inward with respect to the corner portion 614c and extends alongside the corner portion 614c. In the corner portion 615c, the extending direction changes. In the present embodiment, the extending direction of the metal electrode 615 that extends from one end portion of the wiring line 115 to the other end portion of the wiring line 115 changes from the x-axis minus-direction to the y-axis plus-direction in the corner portion 615c.

The extending portion 615a extends from the corner portion 615c toward the y-axis plus-direction. The extending portion 615b is connected to the extending portion 614b via a U-shaped portion 616 and extends alongside the extending portion 614b.

Particularly, the extending portion 615b extends from the corner portion 615c toward the x-axis plus-direction. The U-shaped portion 616 is positioned on the x-axis plus-side of the extending portion 615b and the extending portion 614b. The x-axis plus-side of the extending portion 615b and the x-axis plus-side of the extending portion 614b are connected to each other via the U-shaped portion 616.

### Second Embodiment

A power amplifying circuit 202 according to the second embodiment is now described. In the second embodiment and subsequent embodiments, descriptions regarding matters common to the first embodiment will be omitted, and only points different from the first embodiment will be described. In particular, substantially the same actions and effects produced by substantially the same elements will not be repeated in every embodiment.

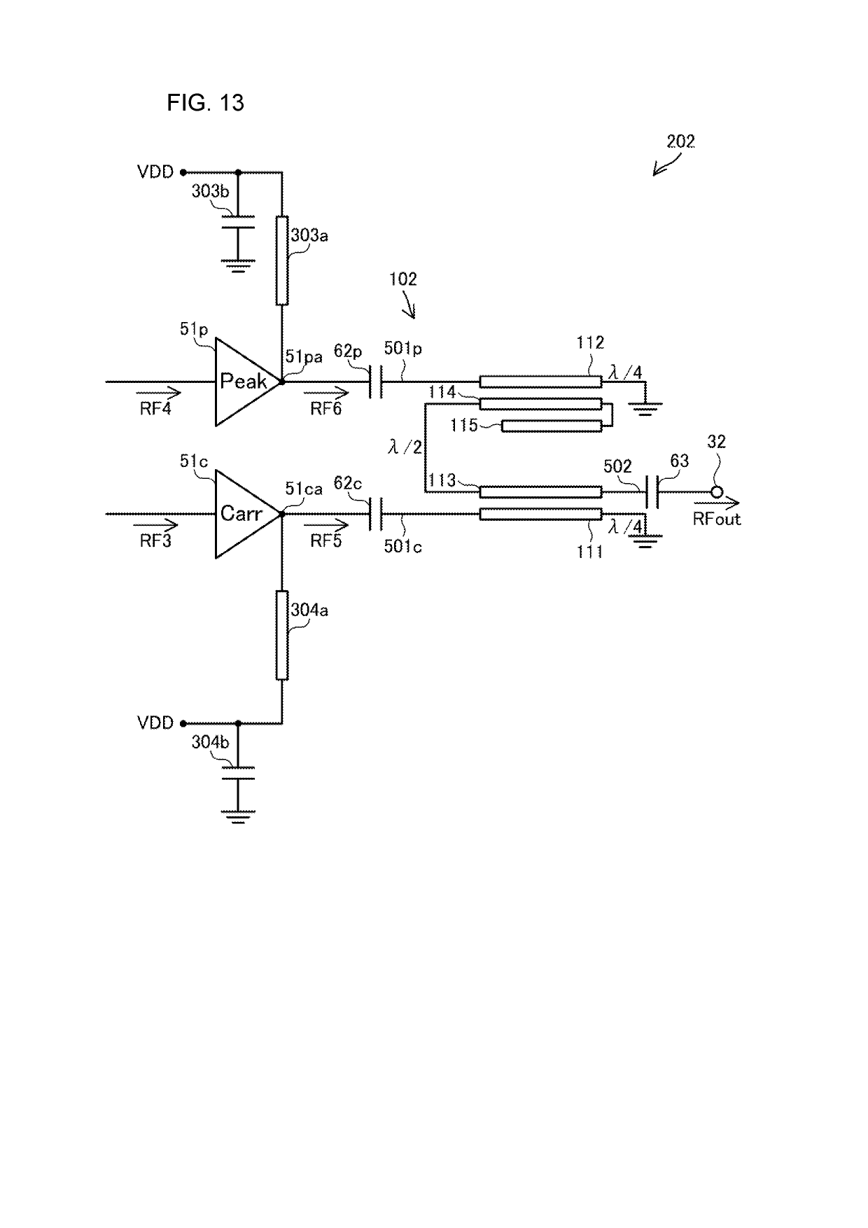

FIG. 13 is a circuit diagram of the power amplifying circuit 202. As illustrated in FIG. 13, the power amplifying circuit 202 is different from the power amplifying circuit 201 according to the first embodiment in that the wiring line 115 has a shorter electrical length.

Compared with the power amplifying circuit 201 illustrated in FIG. 1, the power amplifying circuit 202 includes a balun 102 in place of the balun 101. The electrical length of the wiring line 115 of the balun 102 is shorter than the electrical length of the wiring line 115 of the balun 101.

Specifically, the wiring line 115 is a line that has an electrical length greater than one-eighth and less than one-quarter the wavelength of the signal RF3 that the carrier amplifier 51c amplifies.

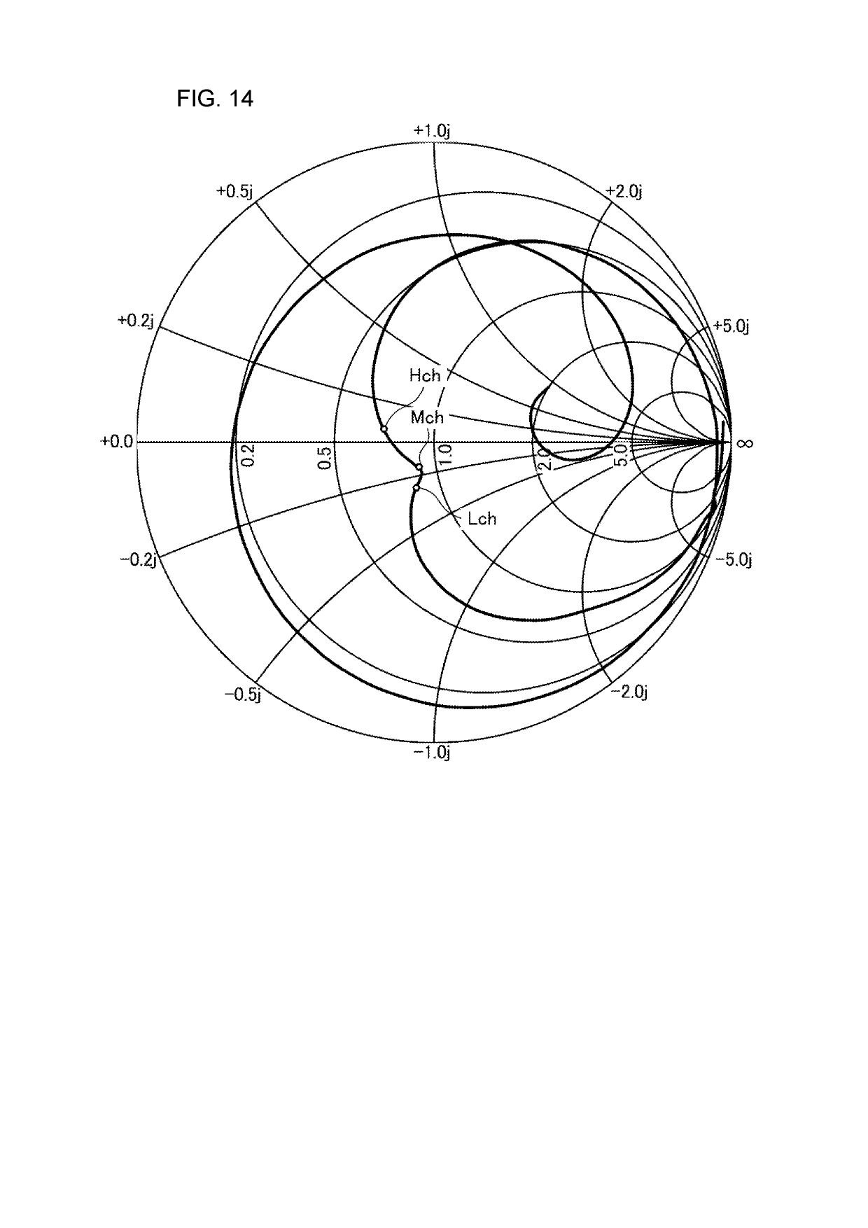

FIG. 14 is a diagram illustrating, on the Smith chart, a simulation result of the frequency variation of S11 when both the carrier amplifier 51c and the peaking amplifier 51p are in operation in the power amplifying circuit 202.

As illustrated in FIG. 14, according to the configuration in which the electrical length of the wiring line 115 is made shorter, it becomes possible to move S11 toward the capacitive side in the range between 120 GHz and 140 GHz, compared with the case illustrated in FIG. 3.

### Layout of Balun 102

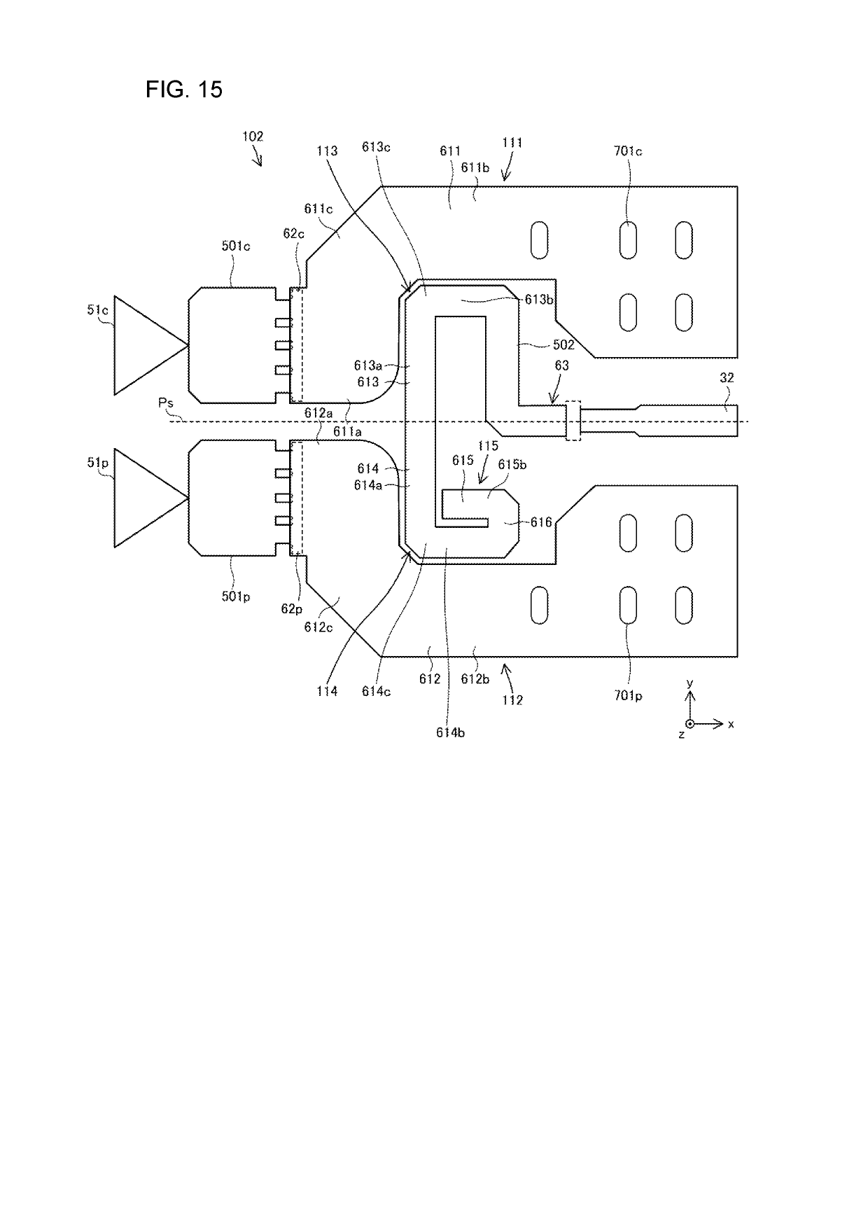

The layout of the balun 102 is now described. FIG. 15 is a plan view of the balun 102 seeing from the top side. As illustrated in FIG. 15, in the balun 102, compared with the balun 101 illustrated in FIG. 12, the metal electrode 615 does not have the extending portion 615a and the corner portion 615c. That is to say, the metal electrode 615 has the extending portion 615b.

The x-axis minus-side of the extending portion 615b is left open-circuit. The x-axis plus-side of the extending portion 615b is connected to the extending portion 614b via the U-shaped portion 616.

### Third Embodiment

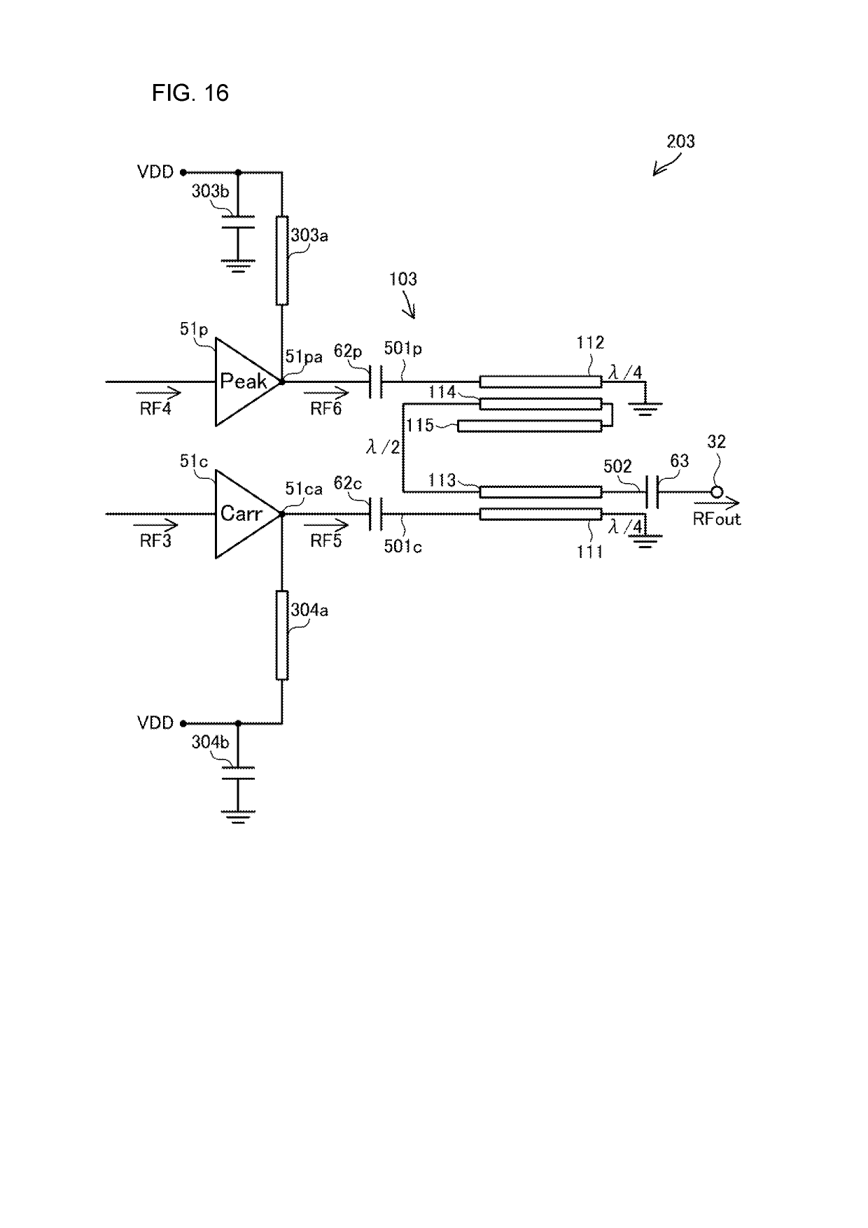

A power amplifying circuit 203 according to the third embodiment is now described. FIG. 16 is a circuit diagram of the power amplifying circuit 203. As illustrated in FIG. 16, the power amplifying circuit 203 is different from the power amplifying circuit 201 according to the first embodiment in that the wiring line 115 has a longer electrical length.

Compared with the power amplifying circuit 201 illustrated in FIG. 1, the power amplifying circuit 203 includes a balun 103 in place of the balun 101. The electrical length of the wiring line 115 of the balun 103 is longer than the electrical length of the wiring line 115 of the balun 101.

Specifically, the wiring line 115 is a line that has an electrical length greater than one-quarter and less than three-eighths the wavelength of the signal RF3 that the carrier amplifier 51c amplifies.

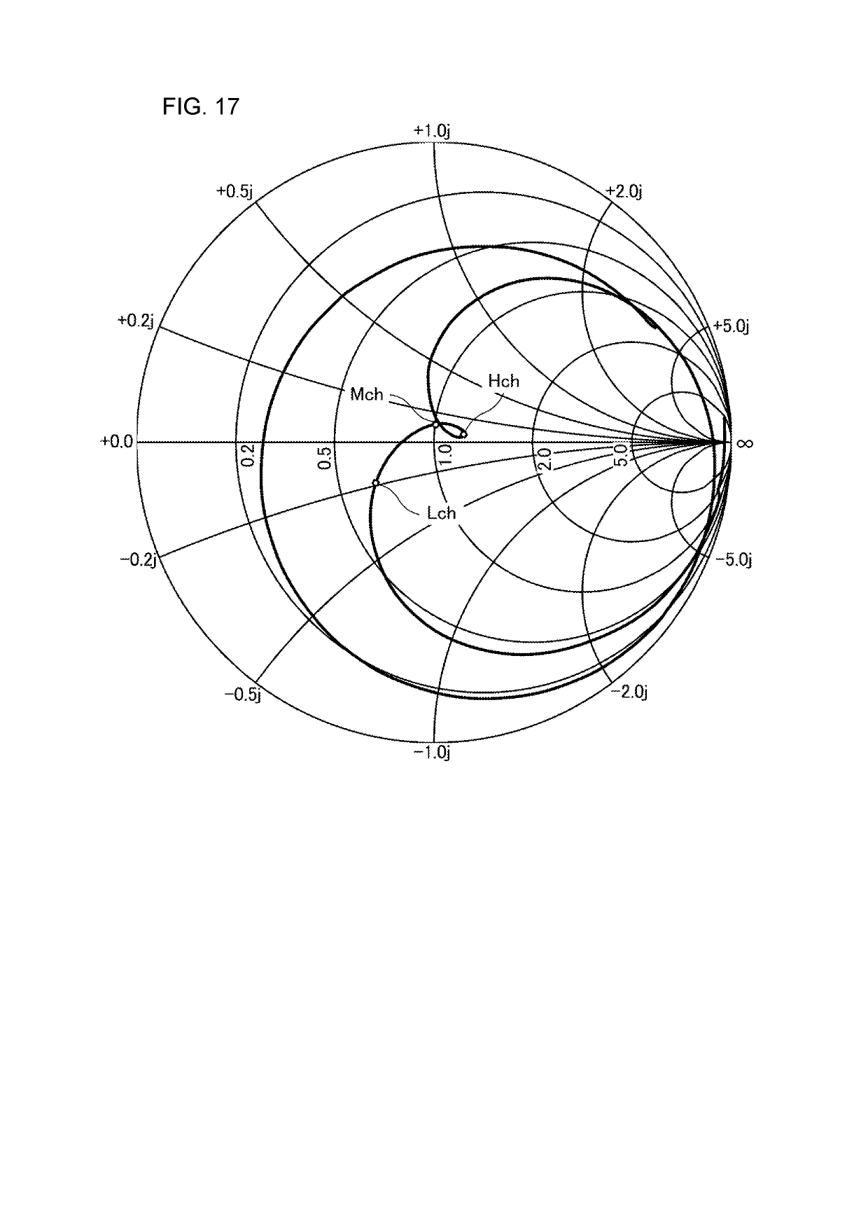

FIG. 17 is a diagram illustrating, on the Smith chart, a simulation result of the frequency variation of S11 when both the carrier amplifier 51c and the peaking amplifier 51p are in operation in the power amplifying circuit 203.

As illustrated in FIG. 17, according to the configuration in which the electrical length of the wiring line 115 is made longer, it becomes possible to move S11 toward the inductive side in the range between 120 GHz and 140 GHz, compared with the case illustrated in FIG. 3.

### Layout of Balun 103

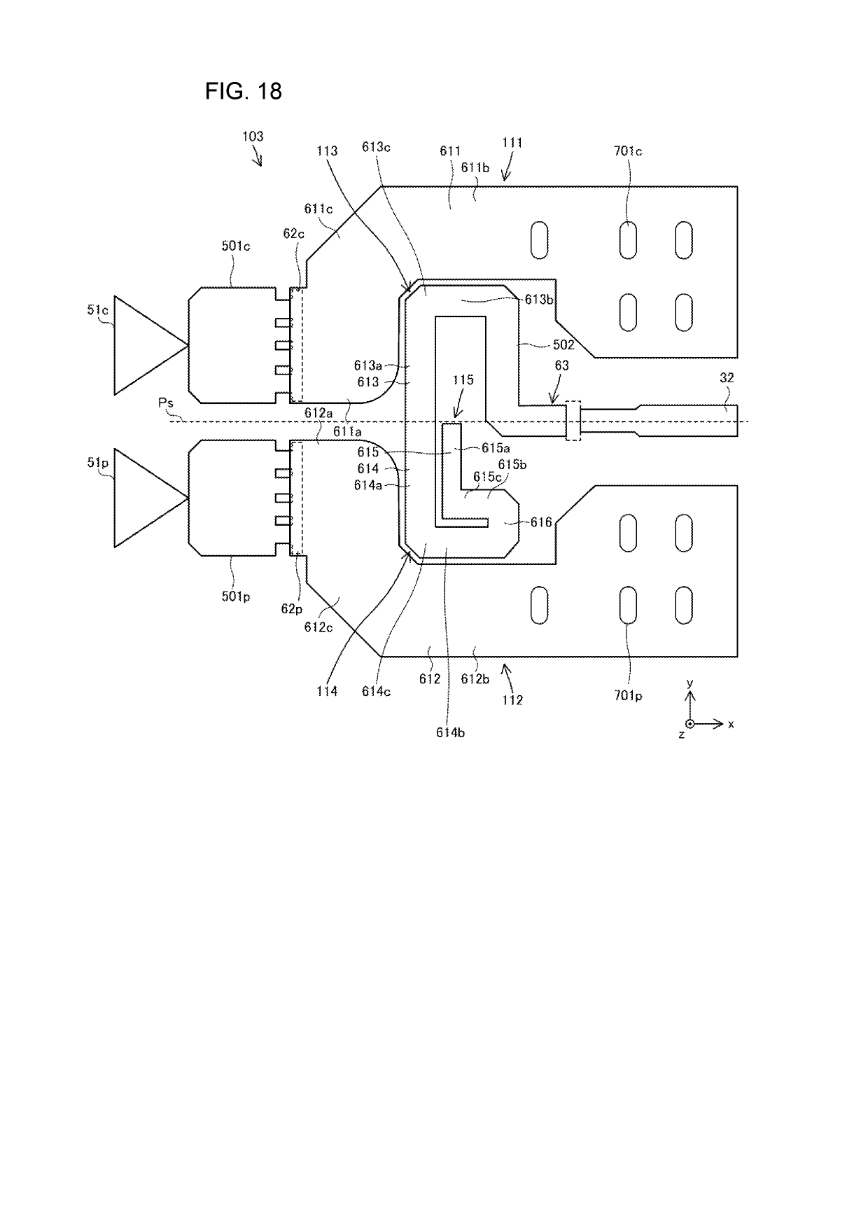

The layout of the balun 103 is now described. FIG. 18 is a plan view of the balun 103 seeing from the top side. As illustrated in FIG. 18, in the balun 103, compared with the balun 101 illustrated in FIG. 12, the extending portion 615a of the metal electrode 615 has a longer length in the y-axis direction and a shorter length in the x-axis direction.

### Fourth Embodiment

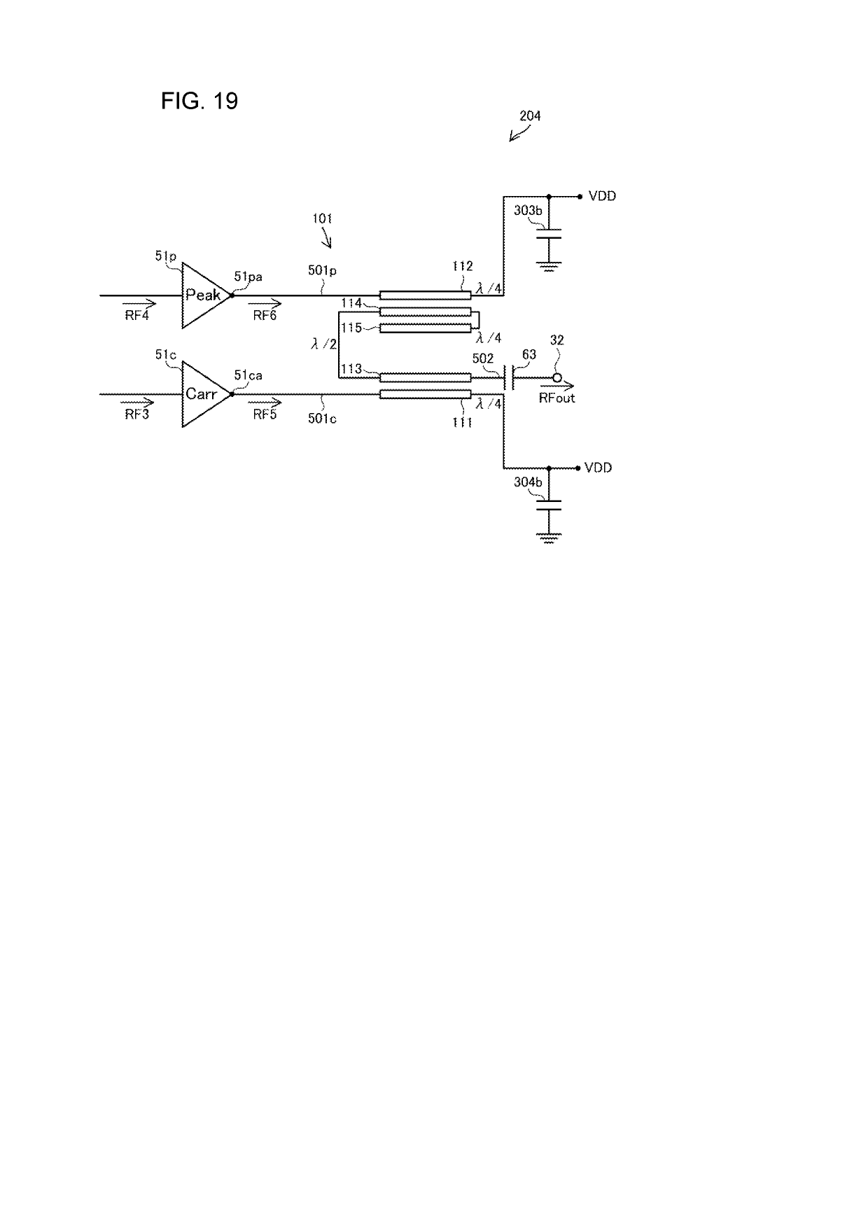

A power amplifying circuit 204 according to the fourth embodiment is now described. FIG. 19 is a circuit diagram of the power amplifying circuit 204. As illustrated in FIG. 19, the power amplifying circuit 204 is different from the power amplifying circuit 201 according to the first embodiment in that the power supply voltages VDD (first reference potential) are supplied from the other end portion of the wiring line 111 and the other end portion of 112.

Compared with the power amplifying circuit 201 illustrated in FIG. 1, the power amplifying circuit 204 does not include the capacitors 62c and 62p and the wiring lines 303a and 304a.

One end portion of the wiring line 111 is connected to the output terminal 51ca of the carrier amplifier 51c via the line 501c. The power supply voltage VDD is supplied to the other end portion of the wiring line 111. The capacitor 304b has one end portion connected to the other end portion of the wiring line 111 and the other end portion connected to the ground.

One end portion of the wiring line 112 is connected to the output terminal 51pa of the peaking amplifier 51p via the line 501p. The power supply voltage VDD is supplied to the other end portion of the wiring line 112. The capacitor 303b has one end portion connected to the other end portion of the wiring line 112 and the other end portion connected to the ground.

The configuration described above also enables the wiring lines 111 and 112 to function as choke coils. Furthermore, it becomes possible to eliminate the DC-cut capacitors 62c and 62p. Because of this, compared with the power amplifying circuit 201, the circuit size of the power amplifying circuit 204 can be reduced.

### Fifth Embodiment

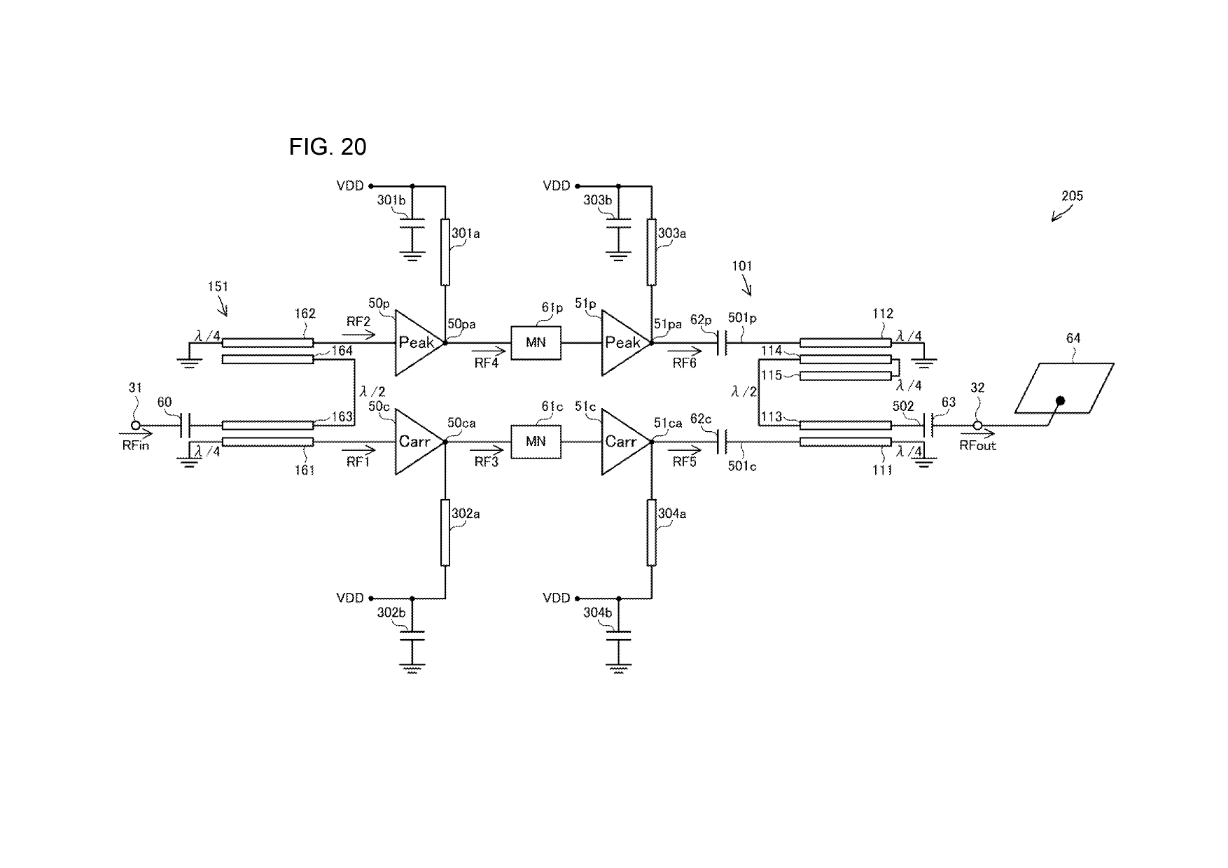

A power amplifying circuit 205 according to the fifth embodiment is now described. FIG. 20 is a circuit diagram of the power amplifying circuit 205. As illustrated in FIG. 20, the power amplifying circuit 205 is different from the power amplifying circuit 201 according to the first embodiment in that a driver stage amplifier and an antenna are illustrated additionally.

Compared with the power amplifying circuit 201 illustrated in FIG. 1, the power amplifying circuit 205 further includes a carrier amplifier 50c, a peaking amplifier 50p, a capacitor 60, inter-stage matching circuits 61c and 61p, a patch antenna 64, a balun 151, wiring lines 301a and 302a, and capacitors 301b and 302b.

The carrier amplifier 50c and the peaking amplifier 50p include amplifying transistors (not illustrated). The balun 151 includes wiring lines 161, 162, 163, and 164.

The balun 151 splits an input signal RFin, which is a single-ended signal, into signals RF1 and RF2. Furthermore, the balun 151 provides impedance matching between a circuit in the preceding stage, which precedes an input terminal 31, and the amplifiers, namely the carrier amplifier 50c and the peaking amplifier 50p.

Particularly, the wiring lines 161, 162, 163, and 164 of the balun 151 are similar to the wiring lines 111, 112, 113, and 114 of the balun 101, respectively. That is to say, the balun 151 is a Marchand balun.

The wiring line 163 has one end portion and the other end portion to which the input signal RFin is supplied from the input terminal 31 via the capacitor 60. The wiring line 161 has one end portion that supplies the signal RF1 to the carrier amplifier 50c and the other end portion connected to the ground, and is coupled with the wiring line 163. This coupling is, for example, coupling between the lines.

The wiring line 164 has one end portion connected to the one end portion of the wiring line 163 and the other end portion that is left open-circuit. The wiring line 162 has one end portion that supplies the signal RF2 to the peaking amplifier 50p and the other end portion connected to the ground, and is coupled with the wiring line 164. This coupling is, for example, coupling between the lines.

The carrier amplifier 50c amplifies the signal RF1 supplied from the one end portion of the wiring line 161 and outputs an amplified signal RF3 from an output terminal 50ca. The amplifying transistor included in the carrier amplifier 50c operates by a power supply voltage VDD supplied via the wiring line 302a, which functions as an inductor, and the output terminal 50ca. The capacitor 302b is a bypass capacitor, and has one end portion to which the power supply voltage VDD is supplied and the other end portion connected to the ground.

The peaking amplifier 50p amplifies the signal RF2 supplied from the one end portion of the wiring line 162 and outputs an amplified signal RF4 from an output terminal 50pa. The amplifying transistor included in the peaking amplifier 50p operates by a power supply voltage VDD supplied via the wiring line 301a, which functions as an inductor, and the output terminal 50pa. The capacitor 301b is a bypass capacitor, and has one end portion to which the power supply voltage VDD is supplied and the other end portion connected to the ground.

The inter-stage matching circuit 61c provides impedance matching between the carrier amplifier 51c and the carrier amplifier 50c. The inter-stage matching circuit 61p provides impedance matching between the peaking amplifier 51p and the peaking amplifier 50p.

The patch antenna 64 is connected to the output terminal 32. The patch antenna 64 functions as a load of the power amplifying circuit 205. In the case where an antenna for the sub-terahertz band is configured using the patch antenna 64, the size of the patch antenna 64 is about 1.1 mm.

Exemplary embodiments of the present disclosure have been described. In the balun 101, the wiring line 111 has one end portion connected to the carrier amplifier 51c and the other end portion connected to the first reference potential. The wiring line 112 has one end portion connected to the peaking amplifier 51p and the other end portion connected to the first reference potential. The wiring line 113 has one end portion and the other end portion connected to the output terminal 32, and is coupled with the wiring line 111. The wiring line 114 has one end portion connected to the one end portion of the wiring line 113 and the other end portion, and is coupled with the wiring line 112. The wiring line 115 has one end portion connected to the other end portion of the wiring line 114 and the other end portion that is left open-circuit, and is electromagnetically coupled with the wiring line 114.

As described above, according to the configuration in which the other end portion of the wiring line 114 is connected to the wiring line 115 that is electromagnetically coupled with the wiring line 114, the wiring lines 114 and 115 can be capacitively coupled with each other. Thus, it becomes possible to suppress the inductive properties of the wiring lines 114 and 115 of the power amplifying circuit 201. When the peaking amplifier 51p is in the off-state, the frequency dependence of the input impedance to the wiring line 114 can be reduced. As a result, it becomes possible to reduce the frequency dependence of the reflected waves reflected at the wiring line 114, which constitute part of the signals generated by the coupling of the wiring lines 111 and 113. Because of this, it becomes possible to make the frequency variation of S21 nearly flat. Accordingly, it becomes possible to suppress the frequency variation of the impedance looking from the carrier amplifier toward the following stage thereof when the peaking amplifier is turned off.

Furthermore, in the balun 101, each of the wiring lines 111, 112, and 115 is a quarter-wavelength line. Furthermore, the line formed by joining the wiring lines 113 and 114 is a half-wavelength line.

According to the configuration described above, it becomes possible to position S11 in the vicinity of the real axis of the Smith chart and to reduce the frequency dependence of S11. Furthermore, splitting of the input signal and combining of the amplified signals amplified by the carrier amplifier 51c and the peaking amplifier 51p can be performed in a favorable manner.

Furthermore, in the balun 103, each of the wiring lines 111 and 112 is a quarter-wavelength line. The line formed by joining the wiring lines 113 and 114 is a half-wavelength line. Furthermore, the wiring line 115 is a line that has an electrical length greater than one-quarter and less than three-eighths the wavelength of the signal RF3 that the carrier amplifier 51c amplifies.

According to the configuration described above, it becomes possible to move S11 toward the inductive side of the Smith chart. Furthermore, splitting of the input signal and combining of the amplified signals amplified by the carrier amplifier 51c and the peaking amplifier 51p can be performed in a favorable manner.

Furthermore, in the balun 102, each of the wiring lines 111 and 112 is a quarter-wavelength line. The line formed by joining the wiring lines 113 and 114 is a half-wavelength line. Furthermore, the wiring line 115 is a line that has an electrical length greater than one-eighth and less than one-quarter the wavelength of the signal RF3 that the carrier amplifier 51c amplifies.

According to the configuration described above, it becomes possible to move S11 toward the capacitive side of the Smith chart. Furthermore, splitting of the input signal and combining of the amplified signals amplified by the carrier amplifier 51c and the peaking amplifier 51p can be performed in a favorable manner.

Furthermore, in the balun 101, the frequency of the signal RF3 that the carrier amplifier 51c amplifies and the frequency of the signal RF4 that the peaking amplifier 51p amplifies are included in the sub-terahertz band.

For example, in the case where a MCT (Magnetic Coupled Transformer) balun is used in the sub-terahertz band, the parasitic capacitance between wiring lines of the transformer becomes greater. This leads to greater loss, and the MCT balun's original performance cannot be achieved in some cases. As described above, in the sub-terahertz band, in the balun 101, the lengths of the wiring lines 111 to 114 can be reduced, and thus, an increase in the circuit size can be suppressed. Furthermore, according to the configuration that uses the balun 101 that has a greater fractional bandwidth and is formed by low-loss line coupling, it becomes possible to provide the balun 101 with favorable performance characteristics.

Furthermore, in the balun 101, the wiring line 114 is provided along the first plane and is formed of the metal electrode 614 that extends from one end portion of the wiring line 114 to the other end portion of the wiring line 114. The wiring line 115 is provided along the first plane and is formed of the metal electrode 615 that extends from one end portion of the wiring line 115 to the other end portion of the wiring line 115. The metal electrode 614 has the extending portion 614b that extends along the x-axis direction. The metal electrode 615 is connected to the extending portion 614b via the U-shaped portion 616 and has the extending portion 615b that extends alongside the extending portion 614b.

As described above, according to the configuration in which the extending portions 614b and 615b, which extend alongside, are connected using the U-shaped portion 616, it becomes possible to lay out the extending portions 614b and 615b in a small area while keeping a constant distance between the extending portions 614b and 615b. Because of this, the extending portions 614b and 615b can be electromagnetically coupled with each other in a favorable manner while effectively utilizing the space.

Furthermore, in the balun 101, the wiring line 114 is provided along the first plane and is formed of the metal electrode 614 that extends from one end portion of the wiring line 114 to the other end portion of the wiring line 114. The wiring line 115 is provided along the first plane and is formed of the metal electrode 615 that extends from one end portion of the wiring line 115 to the other end portion of the wiring line 115. The metal electrode 614 has the corner portion 614c whose extending direction changes. Furthermore, the metal electrode 615 is positioned farther inward with respect to the corner portion 614c.

As described above, according to the configuration in which the metal electrode 615 having an end portion that is left open-circuit is positioned farther inward with respect to the corner portion 614c, where available space is limited, it becomes possible to facilitate the positioning of the wiring line whose both end portions are not left open-circuit on the outward side of the corner portion 614c, where more space is available. This facilitates the layout design of the balun 101 in the semiconductor chip. Furthermore, because space can be utilized effectively, it becomes possible to improve the degree of integration of the semiconductor chip.

Furthermore, in the balun 101, the metal electrode 615 has the corner portion 615c that extends alongside the corner portion 614c.

As described above, according to the configuration in which the extending portion 615b extends alongside the corner portion 614c on the inward side of the corner portion 614c, it becomes possible to lay out the corner portion 615c while keeping a constant distance from the corner portion 614c. Because of this, the corner portions 614c and 615c can be electromagnetically coupled with each other in a favorable manner.

Furthermore, in the balun 101, the wiring line 112 is provided along the first plane and is formed of the metal electrode 612 that extends from one end portion of the wiring line 112 to the other end portion of the wiring line 112. Furthermore, the metal electrode 612 has the corner portion 612c that is positioned farther outward with respect to the corner portion 614c and extends alongside the corner portion 614c.

As described above, according to the configuration in which the corner portion 612c extends alongside the corner portion 614c on the outward side of the corner portion 614c, it becomes possible to lay out the corner portion 612c while keeping a constant distance from the corner portion 614c. Because of this, the corner portions 614c and 612c can be coupled with each other in a favorable manner.

Furthermore, in the power amplifying circuit 201, the carrier amplifier 51c amplifies the signal RF3 and outputs the amplified signal RF5 from an output terminal 51ca. The peaking amplifier 51p amplifies the signal RF4 whose phase is different from the phase of the signal RF3 and outputs the amplified signal RF6 from the output terminal 51pa. The wiring line 111 has one end portion connected to the output terminal 51ca and the other end portion connected to the first reference potential. The wiring line 112 has one end portion connected to the output terminal 51pa and the other end portion connected to the first reference potential. The wiring line 113 has one end portion and the other end portion that supplies the output signal RFout, and is coupled with the wiring line 111. The wiring line 114 has one end portion connected to the one end portion of the wiring line 113 and the other end portion, and is coupled with the wiring line 112. Furthermore, the wiring line 115 has one end portion connected to the other end portion of the wiring line 114 and the other end portion that is left open-circuit, and is electromagnetically coupled with the wiring line 114.

As described above, according to the configuration in which the other end portion of the wiring line 114 is connected to the wiring line 115 that is electromagnetically coupled with the wiring line 114, the wiring lines 114 and 115 can be capacitively coupled with each other. Thus, it becomes possible to suppress the inductive properties of the wiring lines 114 and 115 of the power amplifying circuit 201. When the peaking amplifier 51p is in the off-state, the frequency dependence of the input impedance to the wiring line 114 can be reduced. As a result, it becomes possible to reduce the frequency dependence of the reflected waves reflected at the wiring line 114, which constitute part of the signals generated by the coupling of the wiring lines 111 and 113. Because of this, it becomes possible to make the frequency variation of S21 nearly flat. Accordingly, it becomes possible to suppress the frequency variation of the impedance looking from the carrier amplifier toward the following stage thereof when the peaking amplifier is turned off.

Note that all the embodiments that have been described above are provided to facilitate understanding of the present disclosure and are not to be construed as limiting the present disclosure. The present disclosure can be modified or improved without departing from its spirit, and the present disclosure also includes equivalents thereof. That is to say, ones obtained by suitably modifying the designs of the respective embodiments by those skilled in the art are also included within the scope of the present disclosure as long as they include the features of the present disclosure. For example, each element included in each embodiment as well as its arrangement, material, condition, shape, size, and the like are not limited to those exemplified, and may be suitably changed. Needless to say, each embodiment is for illustrative purposes only, and constituent elements illustrated in different embodiments may be combined or partially exchanged. Resulting embodiments are also included in the scope of the present disclosure so long as the characteristic features of the present disclosure are included.

1. A balun comprising: a first wiring line that has one end portion connected to a carrier amplifier and another end portion connected to a first reference potential; a second wiring line that has one end portion connected to a peaking amplifier and another end portion connected to the first reference potential; a third wiring line that has one end portion and another end portion connected to a terminal, the third wiring line being coupled with the first wiring line; a fourth wiring line that has one end portion connected to the one end portion of the third wiring line and another end portion, the fourth wiring line being coupled with the second wiring line; and a fifth wiring line that has one end portion connected to the another end portion of the fourth wiring line and another end portion that is left open-circuit, the fifth wiring line being electromagnetically coupled with the fourth wiring line.

2. The balun according to 1, wherein each of the first wiring line, the second wiring line, and the fifth wiring line is a quarter-wavelength line, and a line formed by joining the third wiring line and the fourth wiring line is a half-wavelength line.

3. The balun according to 1, wherein the balun according to Claim 1, wherein each of the first wiring line and the second wiring line is a quarter-wavelength line, a line formed by joining the third wiring line and the fourth wiring line is a half-wavelength line, and the fifth wiring line is a line that has an electrical length greater than one-quarter and less than three-eighths wavelength of a signal that the carrier amplifier amplifies.

4. The balun according to 1, wherein the balun according to Claim 1, wherein each of the first wiring line and the second wiring line is a quarter-wavelength line, a line formed by joining the third wiring line and the fourth wiring line is a half-wavelength line, and the fifth wiring line is a line that has an electrical length greater than one-eighth and less than one-quarter wavelength of a signal that the carrier amplifier amplifies.

5. The balun according to any one of 1 to 4, wherein a frequency of a signal that the carrier amplifier amplifies and a frequency of a signal that the peaking amplifier amplifies are included in a sub-terahertz band.

6. The balun according to any one of 1 to 5, wherein the fourth wiring line is provided along a first plane and is formed of a first conductive member extending from the one end portion of the fourth wiring line to the another end portion of the fourth wiring line, the fifth wiring line is provided along the first plane and is formed of a second conductive member extending from the one end portion of the fifth wiring line to the another end portion of the fifth wiring line, the first conductive member has a first extending portion extending along a first direction, and the second conductive member is connected to the first extending portion via a U-shaped portion and has a second extending portion extending alongside the first extending portion.

7. The balun according to any one of 1 to 5, wherein the fourth wiring line is provided along a first plane and is formed of a first conductive member extending from the one end portion of the fourth wiring line to the another end portion of the fourth wiring line, the fifth wiring line is provided along the first plane and is formed of a second conductive member extending from the one end portion of the fifth wiring line to the another end portion of the fifth wiring line, the first conductive member has a first corner portion whose extending direction changes, and the second conductive member is positioned farther inward with respect to the first corner portion.

8. The balun according to 7, wherein the second conductive member has a second corner portion extending alongside the first corner portion.

9. The balun according to 7 or 8, wherein the second wiring line is provided along the first plane and is formed of a third conductive member extending from the one end portion of the second wiring line to the another end portion of the second wiring line, and the third conductive member has a third corner portion that is positioned farther outward with respect to the first corner portion and extends alongside the first corner portion.

10. A power amplifying circuit comprising: a carrier amplifier that amplifies a first signal and outputs a first amplified signal from a first output terminal; a peaking amplifier that amplifies a second signal whose phase is different from a phase of the first signal and outputs a second amplified signal from a second output terminal; a first wiring line that has one end portion connected to the first output terminal and another end portion connected to a first reference potential; a second wiring line that has one end portion connected to the second output terminal and another end portion connected to the first reference potential; a third wiring line that has one end portion and another end portion that supplies an output signal, the third wiring line being coupled with the first wiring line; a fourth wiring line that has one end portion connected to the one end portion of the third wiring line and another end portion, the fourth wiring line being coupled with the second wiring line; and a fifth wiring line that has one end portion connected to the another end portion of the fourth wiring line and another end portion that is left open-circuit, the fifth wiring line being electromagnetically coupled with the fourth wiring line.

What is claimed is:

1. A balun comprising:
a first wiring line that has a first end connected to a carrier amplifier, and a second end connected to a first reference potential;
a second wiring line that has a first end connected to a peaking amplifier, and a second end connected to the first reference potential;
a third wiring line that has a second end connected to a terminal, the third wiring line being coupled with the first wiring line;
a fourth wiring line that has a first end connected to a first end of the third wiring line, the fourth wiring line being coupled with the second wiring line; and
a fifth wiring line that has a first end connected to a second end of the fourth wiring line, and a second end that is left open-circuit, the fifth wiring line being electromagnetically coupled with the fourth wiring line.

2. The balun according to claim 1,
wherein each of the first wiring line, the second wiring line, and the fifth wiring line is a quarter-wavelength line, and
wherein a line formed by joining the third wiring line and the fourth wiring line is a half-wavelength line.

3. The balun according to claim 1,
wherein each of the first wiring line and the second wiring line is a quarter-wavelength line,
wherein a line formed by joining the third wiring line and the fourth wiring line is a half-wavelength line, and
wherein the fifth wiring line is a line that has an electrical length greater than one-quarter and less than three-eighths wavelength of a signal amplified by the carrier amplifier.

4. The balun according to claim 1,
wherein each of the first wiring line and the second wiring line is a quarter-wavelength line,
wherein a line formed by joining the third wiring line and the fourth wiring line is a half-wavelength line, and
wherein the fifth wiring line is a line that has an electrical length greater than one-eighth and less than one-quarter wavelength of a signal amplified by the carrier amplifier.

5. The balun according to claim 1, wherein a frequency of a signal amplified by the carrier amplifier and a frequency of a signal amplified by the peaking amplifier are in a sub-terahertz band.

6. The balun according to claim 1,
wherein the fourth wiring line is along a first plane and is formed of a first conductive member that extends from the first end of the fourth wiring line to the second end of the fourth wiring line,
wherein the fifth wiring line is along the first plane and is formed of a second conductive member that extends from the first end of the fifth wiring line to the second end of the fifth wiring line,
wherein the first conductive member has a first extending portion that extends along a first direction, and
wherein the second conductive member is connected to the first extending portion via a U-shaped portion and has a second extending portion that extends alongside the first extending portion.

7. The balun according to claim 1,
wherein the fourth wiring line is along a first plane and is formed of a first conductive member that extends from the first end of the fourth wiring line to the second end of the fourth wiring line,
wherein the fifth wiring line is along the first plane and is formed of a second conductive member that extends from the first end of the fifth wiring line to the second end of the fifth wiring line,
wherein the first conductive member has a first corner portion whose extending direction changes, and
wherein the second conductive member is positioned farther inward with respect to the first corner portion.

8. The balun according to claim 7, wherein the second conductive member has a second corner portion that extends alongside the first corner portion.

9. The balun according to claim 8,
wherein the second wiring line is along the first plane and is formed of a third conductive member that extends from the first end of the second wiring line to the second end of the second wiring line, and
wherein the third conductive member has a third corner portion that is positioned farther outward with respect to the first corner portion and extends alongside the first corner portion.

10. A power amplifying circuit comprising:
a carrier amplifier that is configured to amplify a first signal and to output a first amplified signal from a first output terminal;
a peaking amplifier that is configured to amplify a second signal whose phase is different from a phase of the first signal, and to output a second amplified signal from a second output terminal;
a first wiring line that has a first end connected to the first output terminal, and a second end connected to a first reference potential;
a second wiring line that has a first end connected to the second output terminal, and a second end connected to the first reference potential;
a third wiring line that has a second end that supplies an output signal, the third wiring line being coupled with the first wiring line;
a fourth wiring line that has a first end connected to a first end of the third wiring line, the fourth wiring line being coupled with the second wiring line; and
a fifth wiring line that has a first end connected to a second end of the fourth wiring line, and a second end that is left open-circuit, the fifth wiring line being electromagnetically coupled with the fourth wiring line.
